(19) United States
(12) Patent Application Publication
(10) Pub. No.: US 2015/0256270 A1
(43) Pub. Date: Sep. 10, 2015

(54) QUANTUM ENTANGLEMENT COMMUNICATIONS SYSTEM

(71) Applicant: Marc S. PALLER, New York, NY (US)

(72) Inventor: Marc S. Paller, New York, NY (US)

(21) Appl. No.: 14/390,168

(22) PCT Filed: Apr. 5, 2013
(86) PCT No.: PCT/US2013/035475

§ 371 Date: Oct. 2, 2014

Related U.S. Application Data
(63) Continuation-in-part of application No. 13/835,937, filed on Mar. 15, 2013, now abandoned.
(60) Provisional application No. 61/620,516, filed on Apr. 5, 2012.

(51) Int. Cl. H04B 10/70; H04B 10/50; H01L 39/24; H01L 27/18; H01L 31/0352; H01L 31/18; H04B 10/40; H04B 10/60

(52) U.S. Cl. CPC H04B 10/70; H04B 10/40; H04B 10/503; H04B 10/60; H01L 27/18; H01L 31/035218; H01L 31/18; H01L 39/24

(57) ABSTRACT

Apparatus for transmitting and receiving information using one or more quantum-entangled particles. The apparatus may include a first substrate including a first row of quantum dots and a second substrate including a second row of quantum dots. The apparatus may also include a beam splitter configured to inject a first particle into a first quantum dot and to inject a second particle into a second quantum dot. A physical property of the first particle may be in a quantum-entangled state with a physical property of the second particle. The apparatus may further include a first wave source configured to move the first particle along the first row of quantum dot, and a second wave source configured to move the second particle along the second row of quantum dots.

### CROSS-REFERENCE TO RELATED APPLICATIONS

This application claims the benefit of U.S. Provisional Application No. 61/620,516, filed Apr. 5, 2012 and is a continuation-in-part of U.S. Nonprovisional patent application Ser. No. 13/835,937, both of which are hereby incorporated by reference in their entireties

### BACKGROUND

Communication networks today transmit information over media that are difficult to secure. The media often include one or more copper wires, coaxial cables, optical fibers or optical paths. Each of these forms of communication can potentially be blocked, jammed, intercepted, detected and/or interfered with. It would be desirable, therefore, to provide apparatus and methods for a communication system that have reduced probability of being obstructed by one or more outside forces.

Quantum entanglement occurs when particles such as molecules, electrons, photons, and even small diamonds interact under certain conditions. These particles, after the interaction, are considered to be in an “entangled state.”

One characteristic of the quantum-entangled state is that if the entangled particles are separated, a measurement of a physical property of one entangled particle immediately affects the physical property of the other entangled particle. For example, if two electrons become entangled and subsequently separated, a measurement made of the first electron's spin state will automatically affect the spin state of the second electron. In this example, if the electron spin of the first electron was measured to be a clockwise spin, then the spin of the second particle, when measured at a later point in time, will be found to have a counterclockwise spin. This holds true irrespective of when the measurement of the first particle took place.

The creation of entangle particles is discussed in “Carbon Nanotubes as Cooper-Pair Beam Splitters,” L. G. Herrmann et al., Physical Review Letters, Jan. 11, 2010, which is hereby incorporated by reference herein in its entirety.

Transferring entangled electron between two quantum dots is discussed in “On-demand single-electron transfer between distant quantum dots,” P. G. McNeil et al., Nature, Sep. 22, 2011, which is hereby incorporated by reference herein in its entirety.

Manipulating the orientation of an entangled particle is discussed in “Ultrafast optical rotations of electron spins in quantum dots,” A. Greilich et al., Nature Physics, April 2009, which is hereby incorporated by reference herein in its entirety.

However, the need for a communication system using quantum entangled particles for receiving and transmitting information has not been addressed. Therefore, apparatus and methods are provided for communicating using entangled particles as a means for transmitting and/or receiving information.

### BRIEF DESCRIPTION OF THE DRAWINGS

FIG. 1 shows illustrative apparatus in accordance with the principles of the invention;

FIG. 2 shows illustrative apparatus in accordance with the principles of the invention;

FIG. 3 shows illustrative apparatus in accordance with the principles of the invention;

FIG. 4 shows illustrative apparatus in accordance with the principles of the invention;

FIGS. 5A-5C shows illustrative apparatus in accordance with the principles of the invention;

FIG. 6 shows illustrative apparatus in accordance with the principles of the invention;

FIG. 7 shows illustrative apparatus in accordance with the principles of the invention;

FIGS. 8A-8C shows illustrative apparatus in accordance with the principles of the invention;

FIG. 9 shows illustrative apparatus in accordance with the principles of the invention;

FIG. 10 shows illustrative apparatus in accordance with the principles of the invention;

FIGS. 11A-11B show illustrative apparatus in accordance with the principles of the invention;

FIG. 12 shows illustrative apparatus in accordance with the principles of the invention;

FIG. 13 shows illustrative apparatus in accordance with the principles of the invention;

FIG. 14 shows illustrative apparatus in accordance with the principles of the invention;

FIG. 15 shows illustrative apparatus in accordance with the principles of the invention;

FIG. 16 shows illustrative apparatus in accordance with the principles of the invention;

FIG. 17 shows illustrative apparatus in accordance with the principles of the invention;

FIG. 18 shows illustrative steps of a process in accordance with the principles of the invention;

FIG. 19 shows illustrative steps of a process in accordance with the principles of the invention;

FIG. 20 shows illustrative steps of a process in accordance with the principles of the invention; and

FIG. 21 shows illustrative steps of a process in accordance with the principles of the invention.

### DETAILED DESCRIPTION OF THE DISCLOSURE

### A. Introduction

The apparatus and methods of the invention relate to a quantum entanglement communication system. The communication system may include the ability to create entangled particles, extract the entangled particles, separate the entangled particles from one another physically, change the quantum state of a first particle and detect resultant change in the second particle's quantum state.

### B. Creating and Extracting Entangled Particles

The apparatus and methods of the invention may include apparatus for creating, extracting, and initially separating entangled particles. The entangled particles may be molecules, electrons, photons, or any other desirable entangled particle.

The apparatus may include a solid-state circuit. The solid-state circuit may be fabricated on a substrate using electron beam lithography, thin film deposition and/or any other suitable technique. The circuit, when activated, may create entangled electrons. The circuit may subsequently eject the entangled electrons from the material in which the entangled electrons were created.

In exemplary embodiments, the circuit may include a nanotube connected to two thin film metallic electrodes and a central superconducting finger. The electrodes may be normal, or non-superconducting.

In some embodiments, shadow evaporation techniques, or other suitable techniques, may be used to fabricate contacts for the normal and superconducting conductors. The normal contacts may include a few nanometers (nm) of Ti (titanium). In these embodiments, the Ti may enhance film adhesion to the substrate. The normal contacts may additionally or alternatively include a few tens of nanometers of Au (gold) or of Pd (palladium).

The nanotube may be a single wall carbon nanotube. The single wall carbon nanotube may be manufactured by chemical vapor deposition. The nanotube may be aligned with the normal electrodes. The nanotube may bridge between the two electrodes and may be in communication with the superconducting electrode.

The nanotube may include two or more quantum dots. The quantum dots may be engineered in the single wall carbon nanotube. Alternatively, two carbon nanotubes may be fabricated, each nanotube including a quantum dot.

The central superconducting electrode included in the circuit may be used as a source of entangled particles. In some embodiments, a singlet pairing of Cooper pairs in the superconductor may be a source of spin entangled electrons.

The central superconducting electrode may have a width that may be in the range of less than about 1 nm to over about 200 nm. For example, the width of the superconducting electrode may be about 10, 20, 30, 50, 100, 200 nm, or any integer value therebetween. It should additionally be noted that the central superconducting electrode may include an aluminum/palladium bilayer of a width of Al (˜100 nm)/Pd (˜3 nm). The contacts may have resistances as low as a few tens of k′Ω between the normal and superconducting reservoir

The circuit may operate to eject the Cooper pairs from the superconductor. The pairs may be ejected by operating the circuit as a beam splitter. In some embodiments, the circuit may operate as a Cooper-pair beam splitter, to create, eject and then split the Cooper pairs of entangled electrons. Thus, the beam splitter may operate to inject a split pair of electrons into the quantum dots included in the single wall carbon nanotube. One electron may be injected into one of the quantum dots, and the other electron may be injected into the other quantum dot.

For example, in some embodiments, the circuit may be operated by biasing the central superconducting electrode. In such embodiments, a current may flow from the superconducting electrode along the nanotube to the normal electrodes. This may generate an applied bias voltage that may be smaller than the energy gap of the superconductor. This may be the result of Cooper-pair injection. The sub gap current may be enhanced by tuning the circuit to degeneracy points of two quantum dots with the help of capacitively coupled side gate electrodes.

The circuit substrate may include a highly doped Si (silicon) substrate. The substrate may include a layer of SiO₂ having a thickness of about 500 nm, or any suitable thickness. The layer may operate as a global back gate. The two side gates may have voltages that can be tuned to control the two normal conductors, which may represent the left and right sides relative to the central superconducting electrode of the circuit. The two normal contacts may be separated by a distance of between sub-micrometer and 1 μm, or more.

The circuit may be operated as a series double quantum dots by setting V_{sc}=0 and Vₙ≠0, where “sc” is the superconducting electrode and “n” the normal electrode. The circuit may be operated as a beam splitter by setting V_{sc}≠0 and Vₙ=0. The left and right sides of the circuit may have a differential conductance that may be qualitatively the same dependence as a function of V_{sc}, V_{gl} or V_{gr}, where V_{gl} and V_{gr} are the left and right gate voltages. In some embodiments, cooper pairs may be injected when V_{sc}<85 μV.

A sufficiently large magnetic field (e.g., about 45 mT) may be applied perpendicular to the axis of the superconducting finger. The magnetic field may cause the superconducting portion of the circuit to conduct under normal conduction. This may also cause the beam splitter (to which may be applied a field of −90 mT) to operate in a normal state. Such a magnetic field may be used to avoid superconductivity of the Al/Pd film.

C. Moving a Single Entangled Particle Away from its Counterpart and Along a Transport Channel

The invention may include apparatus for separating and moving the entangled electrons away from one another. The apparatus may be formed on a substrate.

The separation may be accomplished by moving the electrons in the single wall carbon nanotube quantum dots out of their quantum dot and along a transport channel. The transport channel may extend from the single wall carbon nanotube quantum dot into a quantum ensemble. The quantum ensemble may include a row of quantum dots connected by the transport channel.

The transport channel may be formed in a layer of the substrate. The top of the transport channel may be open or closed.

The entangled electrons may be moved along the quantum dots included in the quantum ensemble using one or more suitable methods. For example, an empty compound semiconductor quantum dot located at the beginning of the quantum ensemble, e.g., InAs (indium arsenide), or any other suitable material, may be populated with an entangled electron. The quantum dot may be connected to a second quantum dot via a transport channel.

Once the quantum dot at the beginning of the quantum ensemble is occupied by an electron, the electron may be moved through the transport channel to a second InAs quantum dot. In embodiments including multiple quantum dots connected by a transport channel, the electron may be moved along the plurality of quantum dots connected by the transport channel.

A source of electrons may be used to populate the quantum dots. In some embodiments, the beam splitter described above in Section B may serve as the source of electrons. This may be accomplished by connecting the two quantum dots included in the single wall carbon nanotube described above in Section B to a transport channel that moves electrons from the nanotube quantum dots to a quantum dot in a quantum ensemble.

A single electron may be initialized in a quantum dot located in the quantum ensemble, and then transferred along the transport channel, when desired, to an adjacent quantum dot using a short duration pulse of surface acoustic waves (“SAW”). The SAW may create a moving potential modulation that may trap and transport electrons. A second SAW pulse, travelling in the reverse direction, may be used to return the transferred electron to the first quantum dot.

SAW pulses, or any other suitable potential, magnetic field, electronic field, electromagnetic field and/or microwave field may be applied to the electron to move it along a transport channel.

For example, a populated quantum dot (i.e., a quantum dot with an electron located within the quantum dot) may be depopulated by applying a brief SAW pulse. The SAW pulse may be generated by applying a microwave signal to a transducer. The accompanying potential modulation may move at approximately 3,000 ms⁻¹, capturing the electron from the first quantum dot and transferring it in approximately 1.5 ns to an adjacent quantum dot. The transfer of charge may be apparent by simultaneous step changes in the detector conductance.

In some embodiments, the SAW amplitude may be, for example, a factor of about 2.5 greater than the electrons amplitude. This may assist in ensuring that a single electron is being transferred between the dots.

Two transducers may be used to provide for bidirectional transfer between the quantum dots. In these embodiments, single electrons (or pairs) may be sent backwards and forwards in bursts with pulses comprising tens to hundreds of SAW pulses.

For the purposes of transferring an entangled electron between quantum dots, control pulses such as, for example, three SAW pairs, each SAW pair including a SAW traveling to the left along the transport channel and a SAW traveling to the right along the transport channel, may be first used to show that the system is empty. An electron may be subsequently loaded into the first quantum dot.

In addition to SAW pulses, one or more plunger gates and/or barrier gates may be used to assist in populating and/or depopulating a quantum dot. For example, the transfer of an electron between quantum dots in the quantum ensemble may include using one or more plunger gates and/or barrier gates. In some of these embodiments, a quantum dot may be electronically adjusted by two plunger gates and two barrier gates. Each plunger gate may raise and lower its quantum dot. Each barrier gate may control the degree of energy isolation between the quantum dot and an adjacent quantum dot. A charge in a quantum dot may be determined by its effect on the electrical conductance of high resistance constrictions on the other side of a narrow separation gate.

Initialization of a quantum dot (QD₁) may include using the plunger gates and/or barrier gates. For example, QD₁ may be populated with on or more electrons by lowering a barrier gate (BG₁) and a plunger gate (PG₁). Subsequently, BG₁ may be elevated, isolating QD₁ from its surroundings. PG₁ may then be elevated to depopulate the dot. In some embodiments, the depopulation may include moving a single electron included in QD₁ out of QD₁. In the embodiments in which QD₁ was populated with multiple electrons, QD₁ may be selectively depopulated, leaving one, or more, electrons, as desired.

BG₁ and PG₁ may then be adjusted, step-wise, to their terminal voltages. QD₁ may now contain one, two, or more electrons held close to, but below, the channel potential. An empty dot may be similarly initialized, but with the plunger gate being elevated first. A detector conductance may be used to indicate a number of electrons in each dot.

Illustrative apparatus and methods that may be used to separate and move entangled electrons away from the beam splitter and into a quantum ensemble are now described.

One or more of the carbon nanotube quantum dots included in the beam splitter described above in Section B may be connected to the beginning of a transport channel. After a quantum entangled electron is ejected into the carbon nanotube quantum dot, the electron may travel down a transport channel connected to the carbon nanotube quantum dot and enter a first quantum dot located along the transport channel. This first quantum dot may be a first quantum dot included in a quantum ensemble. In some embodiments, a wave such as a microwave may be used to push the electron out of the carbon nanotube dot and along the transport channel.

Each quantum ensemble connected to one of the carbon nanotube quantum dots may include a row of quantum dots. The two quantum ensembles may be oriented at an angle away from one another. Each row of quantum dots included in the quantum ensemble may have its own transport channel, dimensions and components as described above. Each row may have a sufficient number of quantum dots in order that the separation between the two quantum ensembles at their opposing ends may be, in the range of sub-centimeter to about 5 cm, or more, for example, about 1, 2, 3, 4 or 5 centimeters, or any value therebetween, fractional or otherwise. This may ensure that there are a sufficient number of quantum dots, containing entangled electrons, at the opposing ends to create a quantum ensemble at both ends.

After the electron enters a quantum dot located at the beginning of a quantum ensemble, the electron may then be sent to an adjacent quantum dot by lowering an adjacent quantum barrier and generating a clearing pulse to remove the electron from the quantum dot. This pulse may move the electron along the transport channel into to an adjacent quantum dot. The channel leading to the quantum dot may then be closed once the electron reaches the adjacent quantum dot.

At this time the electron may be moved to the next adjacent quantum dot. This process may be carried out repeatedly until the electron is placed into the last empty quantum dot in the row and its gate may be subsequently closed. This process may be repeated until all of the quantum dots in the quantum ensembles are populated with individual electrons. A plurality of electrons may be moved along the transport channel, between different quantum dots, at the same time.

The electron beam splitter may be run simultaneously with the SAW pulses. This may enable the electron beam to provide electrons to be moved along the transport channel while accompanying apparatus moves the electrons along empty quantum dot located along the channel.

Once each row of quantum dots included in each quantum ensemble is full, a substrate on which the two quantum ensembles were deposited may then be cut. The substrate may be cut in one or more places. For example, the substrate may be cut along a line running between the two quantum ensembles. In some embodiments, line may be located between the two transport channels. The cutting of the substrate may create two separate quantum ensembles. Each substrate may include a row of populated quantum dots.

One of the quantum ensembles may be used for transmitting information. The other quantum ensemble may be used for receiving the information.

In some embodiments, the quantum ensemble used as a transmitter may include one or more lasers, controllers, electric, magnetic, and or electromagnetic apparatus that may be used by the transmitter to change the spins of the electrons included in the transmitter's quantum ensemble, described in greater detail below.

In some embodiments, the quantum ensemble used as a receiver may include one or more lasers, controllers, electric, magnetic, and or electromagnetic apparatus that may be used by the receiver to detect changes in the spins of the electrons included in the receiver's quantum ensemble, described in greater detail below.

Each electron included on a first quantum ensemble may be in a quantum entangled state with a second electron included on a second quantum ensemble included on the substrate. These two quantum ensembles may be referred to alternately herein as a “pair” of quantum ensembles, or “corresponding” quantum ensembles.

In some embodiments, each electron located at an n^{th} quantum dot on the first quantum ensemble may be in a quantum entangled state with an n^{th} quantum dot on the second quantum ensemble. This may hold true for all quantum dots included on each of the quantum ensembles.

In other embodiments, an electron located at an n^{th} quantum dot on the first quantum ensemble may not necessarily be in a quantum entangled state with an n^{th} quantum dot on the second quantum ensemble. Instead, the electron may be in a quantum entangled state with an electron located at an m^{th} quantum dot in the second ensemble and/or may not be in an entangled state at all with a second electron.

### D. Illustrative Quantum Transmitter and Receiver

The systems and methods of the invention may include a transmitter referred to herein as “the transmitter.” The transmitter may change the spin of a single electron and/or two or more electrons included a first quantum dot ensemble. The transmitter may be located in a first device, or in a quantum network.

The systems and methods of the invention may include a receiver referred to herein as “the receiver.” The receiver may detect the corresponding change in spin(s) of a single electron and/or two or more electrons included in a second quantum dot ensemble. The electron(s) in the second quantum dot ensemble may be in a quantum entangled state with the electron(s) in the first quantum dot ensemble. The receiver may be located in a second device, or in a quantum network.

The transmitter may be included in a transceiver. The receiver may be included in a transceiver.

A transmitter may change a spin of one or more electrons to transmit data to the receiver. The receiver, upon detecting a correlated change in spin(s), may translate the spin change into one or more pieces of data. In these embodiments, one or more spin orientations may be correlated with data such as a ‘0,’ ‘1’, a portion of an alphanumeric data set, or any other data described in more detail below.

A transmitter according to the invention may not need any transmission medium between itself and the receiver to transmit data to the receiver. Instead, the transmitter affects a change in spin of a first quantum ensemble to create, in accordance with quantum mechanical principles, a correlated change in spin in a second quantum ensemble. By affecting a correlated spin change detectable by a receiver, the transmitter may be able to transmit spin-related data without any physical transmission medium between the transmitter and the receiver.

Thus a transmitter according to the invention may transmit information to a its corresponding receiver, and a receiver may receive information from its corresponding transmitter, without using one or more cables, wires, optical fibers, dishes, satellites, base/ground stations, repeaters, antennas, cell sites, central offices, telephone poles, network access points, switches, routers, bridges, or any supporting infrastructure to connect the transmitter to the receiver. Additionally neither air waves nor signal carrying or transport infrastructure may be needed for data transmission between the transmitter and the corresponding receiver.

Furthermore, the quantum communication system may transmit and receive information independent of space and, in some embodiments, time. Thus, there may be no loss of signal strength, integrity or cohesion based on spatial distances and/or lapses of time.

The transmitter may include a pump beam. The pump beam may be used to change the spin of a first group of entangled electrons. The receiver may include a probe beam. The probe beam may used to measure the corresponding changes caused by the pump beam on a second group of entangled electrons. Each electron in the first group of entangled electrons may be in a quantum entangled state with an electron in the second group of entangled electrons.

For example, the changing may be done on a first ensemble of quantum entangled electrons. The detecting may be done on a second ensemble of electrons. The first ensemble and the second ensemble may be populated with entangled electrons as described above in Section C.

The pump beam may change the spin of electrons in a first quantum dot ensemble for a period of time necessary for the probe beam to detect the resultant change in the spin of electrons in a second quantum dot ensemble.

Transmitter may include a controller. The controller may be used to change the spin of the electrons using an electric field, magnetic field, or electromagnetic field. The receiver may include a detector. The detector may be used to measure the changes caused by the controller. The changing of the spins may be done on a first ensemble of quantum entangled electrons. The detecting may be done on a second ensemble of electrons. The first ensemble and the second ensemble may be populated with entangled electrons as described above in Section C.

Electrons in a quantum state may have random spins, or spins that are influenced by outside forces called Hamiltonians. In order to reduce this error, numerous quantum entangled electrons may be used so that the sum total of all of the quantum entangled electrons the transmitter influences and the sum total of the influences detected by the receiver determines if a signal has been sent or not. The more quantum entangled electrons used to make up the ensemble, the less likelihood that the signal sent by the transmitter will be from a random event.

However, a single electron may be used to transmit data to a receiver. The receiver may include a second electron that is in a quantum entangled state with the single electron.

### E. Using the Transmitter to Change the Spin of Entangled Electrons in an Illustrative Quantum Ensemble

The methods and apparatus of the invention may include using a transmitter to change the spin of one or more entangled electrons. In some embodiments, the spins of one or more electrons included in a quantum ensemble discussed above in Section C above may be altered using the transmitter.

The transmitter may include a pump beam. The pump beam may fix the orientation of the spins of one or more electrons included in a quantum ensemble in two dimensions. For example, the pump beam may use a magnetic field and a circular laser to fix the orientation of the spin in the x-y plane. The pump beam may then use an optical laser to rotate the spin of the electrons in the z direction.

For example, the pump beam may use periodic optical laser pulses to initialize, in a “z-direction,” the spins of electrons of a quantum ensemble including a plurality of quantum dots (e.g., (In,Ga)As). Each dot may contain, on average, a single electron spin.

In some embodiments, the spins may be polarized along the direction of the light propagation. The direction of light propagation may be parallel to the quantum dot direction of growth. Along the x-axis a magnetic field B may be applied. Pulsed optical pumping with pulses having an area resonant with trion transitions (θ=∫dtd·E/[ h̅], E being the electric field of the laser and d being varying dipole matrix elements) may instantaneously orient the spins along the optical axis.

The transmitter may use ultrafast control laser pulses to induce rotations of electron spins. For example, control pulses with an area of θ=2π pulses may be used, while changing their detuning of the control pulse from an optical resonance.

In some embodiments, the axis of the induced spin rotation may be determined based on the polarization of the control laser. Additionally, the rotation angle may be computed based on control pulse's photon energy detuning from the optical resonance.

In some embodiments, the receiver may include a probe beam. The probe beam may include a laser. In some embodiments, the probe beam may fix the orientation of the spins of one or more electrons included in a quantum ensemble in two dimensions. For example, the probe beam may use a magnetic field and a circular laser to fix the orientation of the spin in the x-y plane. The probe beam may then use an optical laser to rotate the spin of the electrons in the z direction.

The ellipticity of the probe laser may be then used to measure the precession of spins of a quantum ensemble in the z direction. The precession may be proportional to the spin polarization along the optical z axis. The spin vector may oscillate about B and may be represented on a Bloch sphere by y-z plane precession.

In some of these embodiments, transmitter calibration may include using the probe beam to collect data on various parameters. These parameters may include a peak amplitude and its corresponding period when there may be a change.

In some embodiments using a binary transmitting system, in which a first alignment of electron spins is 1 and a second substantially opposite alignment of electron spins is a 0, the calibration may include transmitting consecutive changes at various time intervals to determine the optimal rest period. This period, in conjunction with the peak amplitude, may be used to determine when a 1 may be transmitted or if 0 may be transmitted. This may be performed in conjunction with the receiver to determine if there may be a need to account for any discrepancies.

In some embodiments using a numeric transmitting system, data to be transmitted by the transmitter may be converted using BASE-64 encoding, or any other suitable encoding, into a text string. The text string may be encoded into a number using a similar encoder. The resulting number may be converted into a radian value that may range from 0 to π. The pump beam may then alter the spin of its quantum ensemble to that specific radian value, thereby increasing the amount of transmitted data, for example, by many orders of magnitude dependent upon the size of the original data.

A transmitter according to the invention may additionally, or alternately, utilize purely electronic methods and hybrid electronic-optical methods for transmitting data.

In exemplary embodiments, the transmitter may consist of a set of magnetic and/or electrical current generating solid state components on opposing sides of a quantum dot ensemble. This apparatus may be used to cause the quantum entangled electrons to change their spin state. Because electrons by themselves are charged, applying a magnetic or electrical field of sufficient strength near them can cause them to alter their spin state while allowing the quantum entangled electrons to stay in the quantum state. Electron spin resonance (“ESR”) is one such method for achieving this, while there are others including superconducting quantum interference devices (“SQUIDS”).

### F. Using the Receiver to Detect the Spin of Entangled Electrons in an Illustrative Quantum Ensemble

A receiver according to the invention may include the probe beam described in Section E above to detect spin entangled electrons.

In some embodiments using a binary receiving system, the calibrated data (above) may be used together with measurements from the probe beam to determine whether a 1 or a 0 was transmitted. In some embodiments, the probe beam may acquire measurements, in the range from, at least a fraction, to about 10, or more, for example, 2, 3, 4, 5, or 10, or any value therebetween, fractional or otherwise, times faster than the rest period.

In some embodiments using a numeric receiving system, the probe beam may measure a quantity which may be converted into a correlated spin change. The resulting radian value representing the spin change may be decoded back into a number and then decoded back into a string and decoded back into the data. This may be parallel to a numeric transmitting system in which decoders may be used.

A receiver according to the invention may additionally, or alternately, utilize purely electronic methods and hybrid electronic-optical methods for receiving data.

For example, the receiver may include a set of magnetic and/or electrical solid-state components on opposing sides of a quantum dot ensemble. This apparatus may be used to indirectly read changes to the quantum entangled electrons' spins. Because electrons by themselves are charged, measuring an effect of a quantum entangled electron spin on a magnetic field, the inducement of a magnetic field, or influence of the spin on an electrical field or current, allows for an indirect measurement of the quantum entangled electron spin. This indirect measurement permits the quantum entangled electrons to stay in the quantum state.

ESR is one such method of indirectly measuring the spin of a quantum entangled electron. Other such methods include SQUIDS.

### G. Controlling the Transmitter

The transmitter according to the invention may include a controller.

In some optical embodiments, the controller may control the pulses of a pump beam in the transmitter's apparatus. Data to be transmitted may be fed into the controller, where it may be then converted into appropriate pulses. The pulses may be sent to the pump beam in conjunction with the type of transmitting system desired (i.e., binary or numeric). The pump beam may subsequently pulse a quantum ensemble with the optical pulse(s) necessary to manipulate the spins of the electrons based on the data to be transmitted. This manipulation of the spins may initiate the transmission of the incoming data to the receiver.

In some electric/magnetic/electromagnetic embodiments, the controller may include apparatus to induce one or more magnetic, electric, and/or electromagnetic fields. The controller may receive data to be transmitted. The controller may subsequently apply one or more magnetic and/or electric fields on a quantum ensemble in conjunction with the type of transmitting system desired (i.e., binary or numeric). The fields applied may manipulate the spins of the electrons based on the data to be transmitted. This manipulation of the spins may initiate the transmission of the incoming data to the receiver.

### H. Controlling the Receiver

In some embodiments, the receiver may include a controller.

In some optical embodiments, the controller may pulse the probe beam included in the receiver's apparatus on to the quantum ensemble. The controller may pulse the probe beam based at least in part on transmitter calibration data received from the transmitter. The probe beam may then detect any changes in spin as described in Section E above.

In some embodiments, the controller may be used to detect changes in one or more magnetic and/or electric fields surrounding an electron included in a quantum ensemble. In some embodiments, transmitter calibration data may be used to detect the changes.

Changes in spin of electron(s) detected by the receiver may be measured, according to one or more of the methods described above, and subsequently transmitted to the controller. The controller may then convert the measurement, depending on the type of transmission (i.e., binary or numeric), into a datagram. The controller may stream the datagram to its next destination based on routing information included in the datagram.

### I. Illustrative Quantum Communication System (“QCS”)

A. Construction of an Illustrative Solid-State, Uni-Casting, One-Way, QCS Apparatus for Transmission of One or More of Voice, Data and Other Suitable Information from a First Device to a Second Device.

These embodiments may include creating two quantum ensembles on a quantum ensemble using one or more of the apparatus or methods described above in Section B through Section H, or any other suitable apparatus or methods. After both quantum ensembles are populated with entangled electrons, the quantum ensemble may be cut and the two quantum ensembles separated.

One of the quantum ensembles may be used as a transmitter. The transmitter may be placed into a new apparatus, or replace circuitry in existing apparatus, in a first device. The transmitter may be used to transmit voice and/or data in a one-way direction, from the first device to a second device. The first device and/or the second device may be a computer, phone, television, radio station, boom box, or any other apparatus suitable for one-way communications.

The quantum ensemble used as a transmitter may include one or more lasers, controllers, electric, magnetic, and or electromagnetic apparatus that may be used by the transmitter to change the spins of the electrons included in the transmitter's quantum ensemble.

The other quantum ensemble may be used as a receiver. The receiver may be placed into new, or replace existing circuitry, in the second device. The receiver may receive transmission from the transmitter.

The quantum ensemble used as a receiver may include one or more lasers, controllers, electric, magnetic, and or electromagnetic apparatus that may be used by the receiver to detect changes in the spins of the electrons included in the receiver's quantum ensemble.

B. Construction of an Illustrative Solid-State, Uni-Casting, One-Way, Multi-Channel, QCS Apparatus for Transmission of One or More of Voice, Data and Other Suitable Information from One Device to Another.

These embodiments may include creating a plurality of quantum ensembles on quantum ensembles using one or more the apparatus or of the methods described above in Section B through Section H above, or any other suitable apparatus or methods. Each pair of quantum ensembles (i.e., quantum ensembles created and populated on the same quantum ensemble) may be used to create one-way multi-channel communications between a first device and a second device. The first device and/or the second device may be a computer, phone, television, radio station, boom box, or any other apparatus.

One quantum ensemble from each pair of quantum ensembles may be used as a transmitter to transmit information from the first device to the second device. These quantum ensembles may be placed into the first device.

Each transmitter may be used as a communications channel to transmit voice and/or data to the second device in a one-way direction. The transmitters, in addition to their lasers, controllers, and optionally a master transmitter controller, may be placed into a new, or replace existing, circuitry for the transmission of voice and/or data in a one-way direction. Each communications channel may be used for information transmission, fail-over transmission, redundancy, and/or to further increase throughput.

In some embodiments, the first device may also include a master transmitter controller. In these embodiments, the master transmitter controller may receive incoming voice and data flow from the first device. In some embodiments, the master controller may translate the incoming data flow into one or more electron spin manipulations that need to be performed to transmit the data to the receiver. The mater transmitter controller may redirect the incoming voice and data flows, or information relating to one or more electron spin manipulations, to one or more transmitters included in the first device.

Additionally, the master transmitter controller may connect to each transmitter's controller. The master transmitter controller may utilize this connection to monitor each of the transmitter's controllers and/or determine a preferred way to utilize the additional channels.

The remaining quantum ensembles may be placed into the second device. These quantum ensembles may be used as receivers to receive information from the first device. These receivers, in addition to their detectors, controller(s), an optionally a master receiver controller, may be placed into new, or replace, existing circuitry that may receive transmission from its corresponding transmitter.

In some embodiments, the second device may also include a master receiver controller. The master receiver controller may be connected to each receiver's controller. The master receiver controller may use this connection to monitor the state of each receiver's respective quantum ensemble. The master receiver controller may additionally, or alternatively, use this connection to detect where incoming data flows from the receivers may be synchronized and/or where redundant information may be removed prior to transmitting the received voice or data digital stream to an appropriate destination.

C. Construction of an Illustrative Solid-State, Uni-Casting, Two-Way, Quantum Entanglement Communications Apparatus for Transmission of One or More of Voice, Data and Other Suitable Information from One Device to Another.

These embodiments may include creating two pairs of quantum ensembles from two quantum ensembles using one or more of the apparatus or methods described above in Section B through Section H above, or any other suitable apparatus or methods. Each pair of quantum ensembles (i.e. quantum ensembles created and populated on the same quantum ensemble) may be used to create a two-way communications channel between a first device and a second device. The first device and/or the second device may be a computer, phone, television, radio station, boom box, or any other apparatus.

The first pair of quantum ensembles may be used to transmit information from the first device to the second device. The second pair of quantum ensembles may be used to transmit information from the second device to the first device.

The first device may include a quantum ensemble from the first pair of quantum ensembles acting as a transmitter with its respective components, a quantum ensemble from the second pair of quantum ensembles acting as a receiver with its respective components, and optionally an additional controller. The apparatus may be may be placed into new, or replace existing, circuitry, in the first device.

In some embodiments, a connection between the transmitter's controller and the receiver's controller to the additional controller may be used for additional network overhead commands. The additional network overhead commands may be added to a signal being transmitted by the transmitter to the second device.

The additional controller may be configured to receive information from one or more devices included in the first electronic device and transmit the information to the transmitter's controller. For example, the additional controller may receive data from a processor or a microphone. The additional controller may transmit the data to the transmitter's controller for data transmission. The additional controller may also be configured to receive information from the receiver's controller and transmit the information to one or more devices included in the first electronic device.

For example, in the embodiments in which the receiver, transmitter and additional controller are part of a mobile phone, the additional controller may receive voice data and text data substantially simultaneously. The additional controller may then transmit the data to the transmitters controller for data transmission. The controller may also receive both voice data and text data from the receiver's controller. The additional controller may retransmit the voice data to a microphone and the text data to a display based on the data packets being received by the receiver. The retransmission may be based on information included in each data packet received by the receiver.

The second device may include a quantum ensemble from the first pair of quantum ensembles acting as a receiver with its respective components, a quantum ensemble from the second pair of quantum ensembles acting as a transmitter with its respective components, and optionally an additional controller. The apparatus may be may be placed into new, or replace existing, circuitry, in the second device.

In some embodiments, a connection between the transmitter's controller and receiver's controller to the additional controller may be used for additional network overhead commands. The additional network overhead commands may be added to a signal being transmitted by the transmitter to the first device. The additional controller may include one or more of the functionalities of the additional controller in the first device discussed above.

D. Construction of a Solid-State, Two-Way, Multi-Channel, Quantum Entanglement Communications Apparatus for Transmission of One or More of Voice, Data and Other Suitable Information from One Device to Another.

These embodiments may include creating a plurality of pairs of quantum ensembles from quantum ensembles using one or more of the apparatus or methods described in sections “B” through “H” above, or any other suitable apparatus or methods. Each pair of quantum ensembles (i.e., quantum ensembles created and populated on the same quantum ensemble) may be used to create a two-way communications channel between a first device and a second device. The first device and/or the second device may be a computer, phone, television, radio station, boom box, or any other apparatus.

A first group of pairs of quantum ensembles may be used to transmit information from the first device to the second device. A second group of quantum ensembles may be used to transmit information from the second device to the first device. The plurality of communication channels may be used for fail-over, redundancy, and/or to further increase throughput. The number of communication channels used may be equal to the number of channels desired.

The first device may include quantum ensembles from the first group of quantum ensembles acting as transmitters with their respective components, quantum ensembles from the second group of quantum ensembles acting as receivers with their respective components, and optionally a master controller. The apparatus may be may be placed into new, or replace existing, circuitry, in the first device.

In some embodiments incoming and outgoing voice and data may flow past the master controller. The master controller may connect to the transmitters' controllers to monitor each of the transmitter's controllers in order to determine a preferred way to utilize the additional channels for transmitting information. The master controller may connect to the receivers' controllers to determine the most optimal way to utilize the additional receiving channels. The master controller may be used to redirect incoming voice and data flows to the appropriate transmitter or transmitters, which may be based on network overhead commands received from the other transmitter or transmitters.

The second device may include quantum ensembles from the first group of quantum ensembles acting as receivers with their respective components, quantum ensembles from the second group of quantum ensembles acting as transmitters with their respective components, and optionally a master controller. The apparatus may be may be placed into new, or replace existing, circuitry, in the second device.

The master controller included in the second device may execute one or more of the functions implemented by the master controller in the first device.

### J. Creating a Network

E. Construction of an Illustrative Quantum Communications Network (“QCN”).

In order for devices that utilize quantum-entangled communications to interact with other devices using quantum-entangled communications, or other traditional devices utilizing conventional forms of communication, an interconnection network must be provided. An interconnection network according to the invention, and detailed below, may be alternately referred to as a quantum communications network, or “QCN.”

Existing hardware and software, including transmitters, receivers, and switches, in addition to transmitters and receivers in accordance with the invention, may be used to create the QCN.

The QCN may interconnect and manage the interconnection of one or devices that incorporate apparatus described herein.

Additionally, the QCN may interconnect and manage traditional devices with devices in accordance with the invention. In these embodiments, the QCN may act as a transport infrastructure between quantum entangled and non-quantum entangled communication devices.

Furthermore, one or more networks may be connected through more traditional connection modalities to other networks to provide access to those networks or systems that do not support quantum entangled connections, and do not want to add one of the described quantum entanglement communication apparatus to their network or networks.

As a result, the QCN may become a central hub. The QCN may be used to augment, or replace, one or more traditional modes of communication today, such as phone or internet communication.

In some embodiments, one single QCN may be used for all devices to interconnect with each other.

In other embodiments, a plurality of QCNs may be provided. In these embodiments, one or more of the QCNs may be connected to one or more other QCNs. This may form a neural network, using communication protocols such as IP to allow different QCNs to communication with each other. Additionally, this may enable a spatial delocalization of the complete QCN network.

Because of distance and time independence of quantum entanglement, the QCN may exist, in theory, anywhere in the universe and at anytime, which is also true for all quantum-entangled devices.

In some embodiments, the QCN does not require any analogous extensive or expensive transport infrastructure to transmit and receive information from one or more devices.

In other embodiments, in addition to the transmitters and receivers in accordance with the invention, the QCN may also include one or more cables, wires, and/or conventional receivers and conventional transmitters to receive and/or transmit information. These standard forms of communication may enable the QCN to be in electronic communication with devices that do not yet include the transmitters and the receivers in accordance with the invention.

The element of the apparatus that may be connected to, and may be part of, the network, and what may be interconnected through the network depends on the specific use of the apparatus.

For example, an electronic device such as a computer, cell phone, radio, etc., may include both a receiver and a transmitter in accordance with the invention. The QCN may contain the opposite set of entangled particles found in the electronic device in a corresponding transmitter and receiver—i.e., a transmitter including electrons in a quantum entangled state with the electronic device's receiver, and a receiver including electrons in a quantum entangled state with the electronic device's transmitter. These opposite quantum entangled transmitters and receivers are housed in the QCN and represent the endpoint of an interconnection module's (“IM”) physical layer for the quantum entangled transmitter and/or receiver. It should be noted than an IM may be substantially similar to the master controller detailed in Section I Subsection D above.

An electronic device may include a receiver in accordance with the invention, and the QCN may include the corresponding transmitter. An electronic device may include a transmitter in accordance with the invention, and the QCN may include the corresponding receiver. An electronic device may include one or more transmitters and/or one or more receivers according to the invention, and the QCN may include the corresponding transmitter(s) and/or receiver(s). The receiver(s) and transmitter(s) may be in one-way communication and/or two-way communication with the QCN.

The QCN may have built in to its connection interface components that support some form of interconnection model (IM) such as OSI or TCP/IP. The IM may be used to receive data from a conventional transmitter or from a transmitter in accordance with the invention, and transmit the data through the QCN to one or more destinations or to one or more different QCNs. The IM may also be used to receive data from the QCN and transmit the data via a conventional communication network work, or via a transmitter in accordance with the invention.

Data transmission through the QCN may proceed as follows.

A data stream may be received by the QCN from an electronic, external device through the transmitter discussed herein. The data stream may then pass through one or more IM layers whose components are built into each of the QCN's connection interfaces. The data stream may then match up with an appropriate means of transport.

As the data stream passed through the appropriate IM layer components in the QCN, there could be many different end or simultaneous results for the data stream depending on each IM layer's component, such as it being stored, displayed, rejected, directed to one or more other physical layers leading to other devices local within the QCN and/or quantum entangled, retransmission requests sent to the external device if the external device contains a receiver, etc.

In some embodiments, information received and transmitted over the QCN may be similar to a datagram. In some of these embodiments, information transmitted by a transmitter in accordance with the invention may include a header containing routing information and a payload.

In these embodiments, information received by the QCN may inform the IM of the information's destination. For example, a packet address, a port identifier, an IP address, or a telephone number may be used to identify a destination. The IM may then route the data using standard techniques known to those skilled in the art to the specified destination.

The QCN may then retransmit the received data stream by routing, switching or bridging the received data stream utilizing the IM model components in each interface of the QCN to non-quantum entangled and/or quantum entangled interfaces within the QCN and/or are interconnected with the QCN.

In the embodiments in which the QCN network uses IP to route data, received and transmitted data may conform to IP standard protocols. For example, a phone may transmit an IP packet to the QCN. The IM may read the packet and determine to which IP address the information is to be transmitted. The QCN may then ship the information to the specified IP address. The IP address specified may be connected to one or more transmitters with corresponding receivers in a second phone. The IM may then transmit the information to the second phone utilizing one or more of the transmitters.

The QCN may support both unicast and/or multicast data streaming.

It should be additionally noted that, in some embodiments, the QCN may transmit data using TCP protocol.

### K. Calibration of the Transmitter and the Receiver

When in use, the transmitter and receiver may be moved separately from each other in three-dimensional space. This may create a need for the transmitter to send a calibration signal to the receiver in order for the receiver to recalibrate itself. This recalibration may take into account the receiver's positional differences in space relative to the transmitter.

For example, when the transmitter and receiver are first configured and calibrated they are static in space relative to each other. As a result, the degree of spin change may be consistent because the receiver and transmitter are aligned along a spatial plane when calibration occurs. If the receiver is then moved so as to deviate from the original spatial plane that aligned it with the transmitter, spin measurements may be inaccurate in detecting spin change from the transmitter.

Therefore, in some embodiments, a transmitter in accordance with the invention may, periodically or on command, send a calibration signal to the receiver. This may enable the receiver to make a correct spin measurement irrespective of the spatial position of the receiver to the transmitter.

An exemplary calibration signal may include of a start made up of 16 up spins and an end made of 16 down spins. Data can only be sent between the start and end. The exemplary calibration signal described above is exemplary only, and any number of spins, in any sequence, may be used as a calibration signal to calibrate the receiver and transmitter described here.

### L. Exemplary Apparatus and Methods According to the Invention

The invention may include apparatus for transmitting and receiving information using one or more quantum-entangled particles. The apparatus may include a first quantum ensemble including a first row of quantum dots and a second quantum ensemble including a second row of quantum dots. The apparatus may also include a beam splitter configured to inject a first particle into a first quantum dot and to inject a second particle into a second quantum dot. A physical property of the first particle may be in a quantum-entangled state with a physical property of the second particle.

The apparatus may also include a first wave source configured to move the first particle from the first quantum dot into a quantum dot included in the first row of quantum dots, and to move the second particle from the second quantum dot into a quantum dot included in the second row of quantum dots. The apparatus may further include a second wave source configured to move the first particle along the first row of quantum dots, and a third wave source configured to move the second particle along the second row of quantum dots.

The apparatus may additionally include transmitting hardware configured to apply a pulse beam to the first particle to manipulate the physical property of the first particle. The apparatus may further include receiving apparatus configured to apply a probe beam to the second particle to measure the physical property of the second particle.

In some embodiments, the first quantum dot and the second quantum dot may be part of a carbon nanotube. In some embodiments, the beam splitter may be a Cooper-pair beam splitter. In some embodiments, the transmitter may apply the pulse beam using optical laser pulses. In some embodiments, the first particle and the second particle may be electrons and the physical property may be an electron spin. In some embodiments, the first wave source may use a microwave signal to move the first particle and the second particle

In some embodiments, a first laser may be configured to apply a pulse beam to the first particle to manipulate the physical property of the first particle. A second laser may be configured to apply a probe beam to the second particle to measure the physical property of the second particle. The first laser applies the pulse beam using optical pulses.

In some embodiments, the apparatus may also include first apparatus configured to apply a field to the electron. The field may alter the spin of the first electron. The apparatus may also include second apparatus. The second apparatus may be configured to detect a change in the spin of the second electron.

The first apparatus may include a first electromagnet located on a first side of the first electron and a second electromagnet located on a second side of the first electron opposite the first side. The first apparatus may be configured to apply a field to the first electron by applying a voltage to the first electromagnet and the second electromagnet.

The second apparatus may comprise a superconducting quantum interference device “SQUID” that includes superconducting wires configured to circumscribe the second electron. The SQUID may be configured to detect the change in the spin of the second electron by detecting a change in an electric field surrounding the second electron. The change in the electric field surrounding the second electron may be effected by the altering of the spin of the first electron.

The invention may also include apparatus for transmitting and receiving information using one or more quantum-entangled particles. The apparatus may include a wafer. The wafer may include a first substrate including a first row of quantum dots, a second substrate including a second row of quantum dots, and a beam splitter.

The beam splitter may be configured to inject a first particle into a first quantum dot and to inject a second particle into a second quantum dot. A physical property of the first particle may be in a quantum-entangled state with a physical property of the second particle.

The apparatus may also include a first wave source configured to move the first particle from the first quantum dot into a quantum dot included in the first row of quantum dots, and to move the second particle from the second quantum dot into a quantum dot included in the second row of quantum dots. The apparatus may additionally include a second wave source configured to move the first particle along the first row of quantum dots. The apparatus may further include a third wave source configured to move the second particle along the second row of quantum dots.

The apparatus may also include transmitting apparatus. The transmitting apparatus may apply an electric field and a magnetic field to the first particle. The application of the electric field and the magnetic field may alter the physical property of the first particle. The apparatus may additionally include receiving apparatus. The receiving apparatus may detect a change in the physical property of the second particle. The apparatus may further include a detector. The detector may receive a signal from the receiving apparatus.

In some embodiments, the transmitting apparatus may include a first electromagnet located on a first side of the first particle and a second electromagnet located on a second side of the first particle opposite the first side. In some of these embodiments, the transmitting apparatus may apply an electric field to the first particle by applying a voltage to the first electromagnet and the second electromagnet.

In some embodiments, the first particle and the second particle may be electrons and the physical property may be an electron spin.

In some embodiments, the receiving apparatus may detect the change in the electron spin of the second particle using electron spin resonance techniques.

In other embodiments, the receiving apparatus may include a SQUID that includes superconducting wires surrounding the second particle. The SQUID may detect the change in the electron spin of the second particle by detecting a change in an electric field surrounding the second particle.

In some embodiments, the change in the electric field surrounding the second particle may be effected by the altering of the electron spin of the first particle. In some of these embodiments, the signal received by the detector may correspond to the change in the electric field surrounding the second particle.

The invention may additionally include a method for making an ensemble of quantum dots. The method may include fabricating a substrate. The substrate may include a beam splitter. The substrate may also include a first transport channel extending away from the beam splitter and attached to the beginning of a first ensemble of quantum dots. The substrate may further include a second transport channel extending away from the beam splitter and attached to the beginning of a second ensemble of quantum dots.

The method may additionally include generating quantum entangled electrons using the beam splitter and populating the first ensemble of quantum dots and the second ensemble of quantum dots with the quantum entangled electrons. The method may further include cutting the wafer. The cutting may separate the first ensemble of quantum dots from the second ensemble of quantum dots.

The method may also include incorporating the first ensemble into a first electronic device, incorporating the second ensemble into a second electronic device, and using the first ensemble to transmit information from the first electronic device to the second electronic device. The second ensemble may receive the information transmitted by the first ensemble.

In some embodiments, the wafer may be fabricated using e-beam lithography and chemical vapor deposition. In some embodiments, the beam splitter may include a superconductor and the generating may consist of ejecting a Cooper pair of electrons out of the superconductor. In some embodiments, the fabricating may include positioning the end of the first ensemble of quantum dots at a distance at least 2.5 cm away from the end of the second ensemble of quantum dots.

In some embodiments, the first ensemble may transmit information by aligning the spins of the quantum entangled electrons included in the first ensemble along a first direction. In some embodiments, the second ensemble may receive information by detecting the corresponding change in spins of the quantum entangled electrons included in the second ensemble.

The invention may further include a method of transmitting a binary signal. The method may include generating an electromagnetic signal within a first quantum dot ensemble. The first quantum dot ensemble may include a first plurality of quantum entangled electrons. Each of the first plurality of quantum entangled electrons may be confined within a quantum dot. The electromagnetic signal generated may align the spin of each of the first plurality of quantum entangled electrons in a first direction.

The method may also include reading a signal generated by a second quantum dot ensemble. The second quantum dot ensemble may include a second plurality of quantum entangled electrons. Each of the second plurality of quantum entangled electrons may be confined within a quantum dot. The signal may be generated by an alignment of the spins of the quantum entangled electrons in a second direction. The method may additionally include outputting to a processor the binary value 1 or 0 based on the reading of the signal generated by the second quantum dot ensemble.

In some embodiments, each of the first plurality of quantum entangled electrons may be in a quantum entangled state with one of the second plurality of quantum entangled electrons. In some embodiments, the signal generated by the alignment of the spins in the second direction may correspond to the binary value 1 or 0.

In some embodiments, the generating of the electromagnetic signal may be effected using a microwave generator and two electrically charged walls. The first electrically charged wall may have a positive value. The second electrically charged wall may have a negative value. In some embodiments, the first electrically charged wall may be located on a first side of the plurality of first quantum dots. The second electrically charged wall may be located on a second side of the plurality of first quantum dots opposite the first side.

The system and methods of the invention may further include a transmitter. The transmitter may transmit data by aligning spins of quantum entangled electrons. The transmitter may be part of a cellular phone, a computer, or any other suitable electronic device.

In some embodiments, the transmitter may align the spins of the quantum entangled electrons by generating an electromagnetic signal proximal to the quantum entangled electrons. In some embodiments, each of the quantum entangled electrons may be confined within a quantum dot.

In some embodiments, the quantum entangled electrons may be included in a first quantum ensemble. Additionally, each of the quantum entangled electrons included in the first quantum ensemble may be in an entangled state with an electron included in a second quantum ensemble.

The invention may further include a receiver. The receiver may be configured to receive data by detecting a field generated by a change in spin of a quantum entangled electron.

In some embodiments, the receiver may detect the field using a superconducting wire that surrounds the quantum entangled electron.

In some embodiments, the quantum entangled electron may be a first quantum entangled electron. In these embodiments, a change in spin of the first quantum entangled electron may be induced by a change in spin of a second quantum entangled electron. The spin of the first quantum entangled electron may be in a quantum entangled state with the spin of the second quantum entangled electron.

In some embodiments, the data received by the receiver may correspond to one of the binary values 1 and 0. In some embodiments, the receiver may output to a processor the binary value 1 or 0.

The invention may also include a transmitter configured to transmit data by manipulating a spin of an electron. The electron may be a first electron. The electron spin of the first electron may be in a quantum entangled state with an electron spin of a second electron.

The transmitter may be disposed in a first device and may be configured to transmit information to a receiver disposed in a second device. The first device may be different from the second device. The first device may be device may be a mobile phone and the second device may be a communication network.

The manipulating may comprise generating an electromagnetic signal proximate to the electron. The quantum entangled electron may be retained by a quantum dot. The quantum entangled electron may be part of a first quantum ensemble that includes a plurality of quantum entangled electrons. Each quantum entangled electron in the first quantum ensemble may be in an entangled state with an electron in a second quantum ensemble.

The invention may include a method for transmitting information. The method may comprise manipulating a spin of a first electron, wherein the spin of the first electron may be in a quantum entangled state with a spin of a second electron.

The invention may include a receiver configured to receive data by detecting a field generated by a change in spin of an electron. The electron may be a first electron. The electron spin of the first electron may be in a quantum entangled state with an electron spin of a second electron. The field may be detected by a superconducting conductor circumscribing the electron. The change in spin of the first electron may be induced by a change in spin of the second electron. The field may correspond to one of the binary values 1 and 0. The receiver may include a processor configured to output the one of the binary values 1 and 0.

The receiver may be configured to pulse an ensemble of quantum entangled electrons to receive data. The ensemble of quantum entangled electrons may be configured to be pulsed using a laser. The laser may be configured to provide an ellipticity for measuring a precession of spins of the quantum entangled electrons.

The invention may include a method of receiving information. The method may comprise detecting a field generated by a change in an electron spin of an electron.

The invention may include a receiver configured to receive instructions from a user to transmit a piece of information to a destination and a transmitter configured to transmit the information to a controller that may be configured to transmit the information to the destination by manipulating the spin of an electron.

The electron may be a first electron and the spin of the first electron may be in a quantum entangled state with a spin of a second electron located in a communication network. The first electron may be in a first country and second electron may be in a second country. The piece of information includes a network address. The network address may identify a location in the communication network. The network address may be an IP address.

The invention may also include apparatus comprising a first electron including a first spin, a second electron including a second spin and a generator. The generator may be configured to manipulate the first spin of the first electron to transmit a first packet of information to a first device and to manipulate a second spin of a second electron to transmit a second packet of information to a second device.

The first electron and the second electron may be the same electron. The first electron may be different from the second electron. The first packet may include first routing information and the second packet includes second routing information.

The invention may also include a method for manipulating an electron spin of an electron located in a first device to transmit information to a second device and to a third device.

The invention may also include a method for receiving information from a first device and transmitting the information to a second device. The method may comprise detecting a change in a physical property of a first quantum entangled particle, wherein the physical property of the first quantum entangled particle may be in a quantum entangled state with a physical property of a second quantum entangled particle located in the first device. The method may also comprise outputting data based on the detected change. The method may further comprise transmitting the data through a network to a destination identified in the data stream. The method may additionally comprise manipulating a physical property of a third quantum entangled particle, wherein the physical property of the third quantum entangled particle may be in a quantum entangled state with a physical property of a fourth quantum entangled particle located in the second device.

The first quantum entangled particle and the third quantum entangled particle may be located in a communication network. The detecting may comprise sensing a change in an electromagnetic field surrounding the first quantum entangled particle. The manipulating may comprise generating an electric, magnetic or electromagnetic field proximal to the third quantum entangled particle.

The particles may be electrons and the physical property may be an electron spin.

The first quantum entangled particle may be part of a first group of quantum entangled particles, the second quantum entangled particle may be part of a second group of quantum entangled particles, the third entangled particle may be part of a third group of entangled particles, and the fourth entangled particle may be part of a fourth group of entangled particles.

The invention may additionally include a method of manufacturing a communication network. The method may include providing a receiver configured to receive information by detecting a change in a spin of a first electron, providing a transmitter configured to transmit information by manipulating a spin of a second electron and providing a network backbone. The method may also include configuring the receiver to be in electronic communication with a first interconnection module, configuring the transmitter to be in electronic communication with a second interconnection module; and configuring the first interconnection module and the second interconnection module to be in electronic communication with each other over the network backbone.

Although the invention discusses manipulating electrons, in some embodiments positrons may be used in transmitters and receivers according to the invention.

Apparatus and methods in accordance with the invention will now be described in connection with the FIGS. The FIGS. show illustrative features of apparatus and methods in accordance with the principles of the invention. The features are illustrated in the context of selected embodiments. It will be understood that features shown in connection with one of the embodiments may be practiced in accordance with the principles of the invention along with features shown in connection with another of the embodiments.

Apparatus and methods described herein are for illustrative purposes only, and do not in any way limit the scope of the invention. Apparatus and methods of the invention may involve some or all of the features of the illustrative apparatus and/or some or all of the steps of the illustrative methods. The steps of the methods may be performed in an order other than the order shown and described herein. Some embodiments may omit steps shown and described in connection with the illustrative methods. Some embodiments may include steps that are not shown and described in connection with the illustrative methods.

Illustrative embodiments will now be described with reference to the accompanying drawings, which form a part hereof.

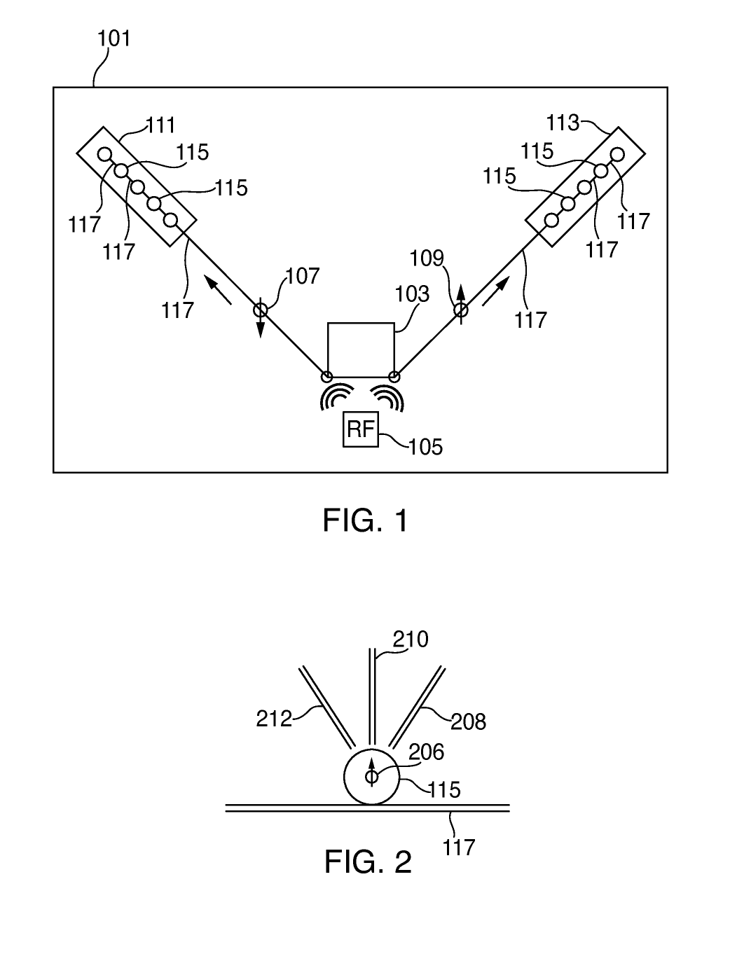

Illustrative embodiments of apparatus and processes illustrated in FIGS. 1-21 in accordance with the principles of the invention will now be described with reference to the accompanying drawings, which form a part hereof. It is to be understood that other embodiments may be utilized and that structural, functional and procedural modifications may be made without departing from the scope and spirit of the present invention. Additionally, one or more features included in FIGS. 1-21 may be added, deleted or modified in accordance with the invention described herein.

FIG. 1 shows illustrative substrate 101 in accordance with the invention. Substrate 101 may be fabricated using thin film deposition techniques, e-beam lithography, chemical vapor deposition and/or any other suitable method.

Substrate 101 may include beam splitter 103, microwave generator 105 and transport channels 117. Substrate 101 may also include electron 107 and electron 109, in addition to quantum dots 115, first quantum ensemble 111 and second quantum ensemble 113.

Beam splitter 103 may include a superconducting electrode, a carbon nanotube with two quantum dots, and one or more normal electrodes (not shown). Beam splitter 103 may include one or more of the apparatus included in the solid state circuit described above in Section B.

Beam splitter 103 may inject a pair of entangled electrons, comprising of electron 107 and electron 109, into the carbon nanotube quantum dots (not shown). Microwave generator 105 may use one or more microwaves to push electron 107 and electron 109 out of the carbon nanotube quantum dots and move them along transport channel 117. Electron 107 may be pushed along transport channel 117 and into a quantum dot 115 located at the beginning of first quantum ensemble 111. Electron 109 may be pushed along transport channel 117 and into a quantum dot 115 located at the beginning of second quantum ensemble 113.

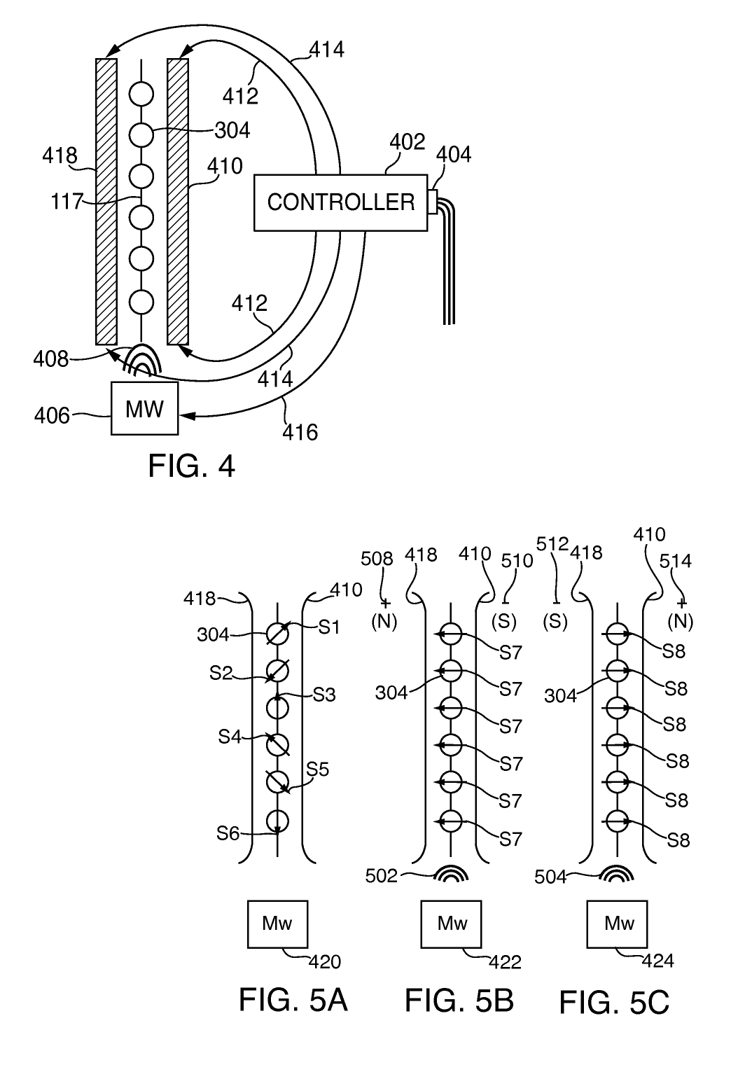

Each of first quantum ensemble 111 and second quantum ensemble 113 may include a plurality of quantum dots 115 connected by a transport channel 117. In addition to quantum dots 115 and transport channels 117, first quantum ensemble 111 may include one or more of the apparatus illustrated in FIG. 4. Additionally, second quantum ensemble 113 may include one or more of the apparatus illustrated in FIG. 7.

Substrate 101 may be fabricated with ensembles 111 and 113 heading in opposite directions. This may be advantageous when cutting substrate 101, as described in more detail below.

In some embodiments, the portion of transport channel 117 located between beam splitter 103 and ensembles 111 and 113 may include one or more quantum dots (not shown). In these embodiments, microwave generator 105 may move an entangled electron out of the carbon nanotube quantum dot, along transport channel 117, through the quantum dots included in transport channel 117, and finally into one of quantum ensembles 111 or 113.

FIG. 2 shows an illustrative transport system in accordance with the invention. The illustrative transport system may include transport channel 117 and quantum dot 115. The illustrative transport system may also include plunger 210, barrier 208 and central gate 212. In FIG. 2, quantum dot 115 is populated with electron 206. Electron 206 may be a quantum-entangled electron that was ejected from beam splitter 103 illustrated in FIG. 1.

Plunger 210, barrier 208 and central gate 212 may be used to assist in electron localization and transmission along transport channel 117 as described in Section C above.

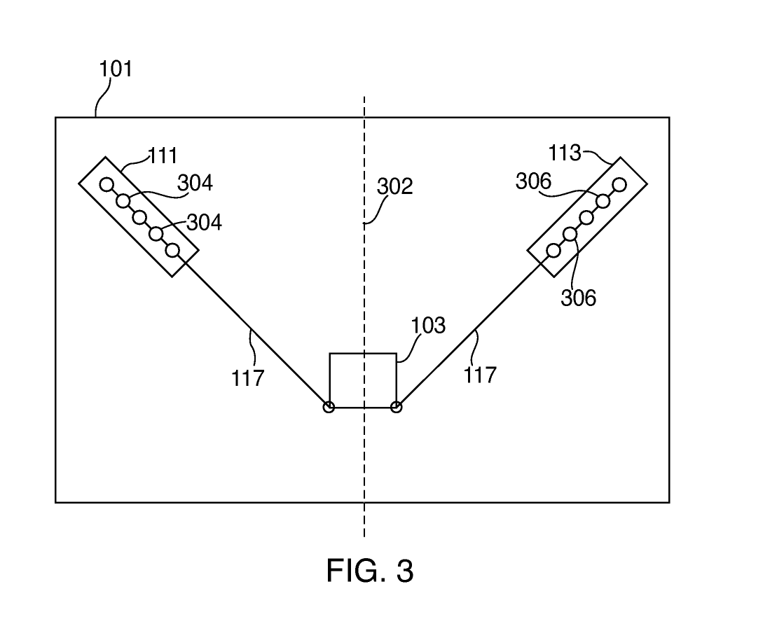

FIG. 3 shows an illustrative method for cutting substrate 101 into two pieces. In FIG. 3, substrate 101 is cut along line 302 to create two separate pieces.

In FIG. 3, first quantum ensemble 111 may include populated quantum dots 304. A populated quantum dot 304 may be a quantum dot that contains an entangled electron. Additionally, in FIG. 3, second quantum ensemble 113 may include populated quantum dots 306. A populated quantum dot 306 may be a quantum dot that contains an entangled electron. Preferably, substrate 101 is cut only after each quantum dot included on first quantum ensemble 111 and second quantum ensemble 113 has been populated.

Any suitable apparatus may be used to cut substrate 101. For example, a diamond saw may be used to cut substrate 101 along line 302. The apparatus used to cut substrate 101 may have a width. Because of the width of the cutting apparatus, the separation of quantum ensemble 111 from quantum ensemble 113 may assist in ensuring that quantum ensembles 111 and 113 are not damaged during the cutting.

Alternative embodiments of the invention include cutting substrate 101 in into any suitable shape. For example, in some embodiments, two or more cuts may be applied to substrate 101 in any suitable direction.

Subsequent to the cutting of the wafer, one half of the wafer may be incorporated into apparatus such as a semiconducting body, hooked up to one or more wires, and subsequently be used to transmit information. The other half of the wafer may be incorporated into a second apparatus, hooked up to one or more wires, and subsequently be used to receive information.

The two halves of the wafer may be incorporated into any apparatus that transmits and/or receives information. For example, a quantum ensemble according to the invention may be incorporated into a cell phone, phone, computer, walkie talkie, or any other suitable communication system.

FIG. 4 shows a portion of an illustrative transmitting system according to the invention. In some embodiments, FIG. 4 may be a detailed view of quantum ensemble 111.

The illustrative transmitting system may include controller 402. Controller 402 may receive information from data input 404. In response to the information received from data input 404, controller 402 may transmit one or more signals to microwave generator 406, component 410 and/or component 418.

Controller 402 may transmit a signal to microwave generator 406 using transmission medium 416. Controller 402 may transmit a signal to component 410 using transmission medium 412. Transmitter 401 may transmit a signal to component 418 using transmission medium 414.

Each of transmission mediums 412, 414 and 418 may be connectors such as wires. Transmission medium 416 may be used to turn on microwave generator 406. Transmission mediums 412 and 414 may be used to apply a voltage to components 410 and 418.

A signal sent to microwave generator 406 may initiate microwave generator 406 to generate microwave 408. The signal transmitted to microwave generator 406 may determine both the wavelength and the frequency of microwave 408.

A signal sent to one of components 410 and 418 may cause the component to take on a charge, and/or generate a magnetic and/or an electrical field. Component 410 and 418 may be any component that is able to generate a field. For example, component 410 and 418 may be metal plates, electromagnets or wires.

In some embodiments, components 410 and 418 may use electron spin resonance (ESR) or superconducting quantum interference devices (SQUIDS) to generate an electric field.

The generation of a field by one or both of components 410 and 418 may cause the spin of all of the quantum entangled electrons confined in quantum dots 304 to align in the same direction. This effect is demonstrated in greater detail at FIGS. 5A, 5B and 5C below.

Although FIG. 4 illustrates apparatus for using electrical and/or magnetic fields to align the spin of entangled electrons, other apparatus such as lasers can be used to manipulate the electron spin, as detailed in “E” above.

FIG. 5A shows a portion of an illustrative transmission system in accordance with the invention. The portion of the illustrative transmission system illustrated in FIG. 5A may include six populated quantum dots 304, microwave generator 420, component 410 and component 418. In FIG. 5A, microwave transmitter 420 is not generating any microwave signals. Additionally, components 410 and 4108 are not generating a magnetic or an electrical current. As a result, the spins S1, S2, S3, S4, S5 and S6, of each quantum dot 304 are different and do not exhibit any uniformity. It follows that no information is being transmitted by the illustrative transmission system.

FIG. 5B shows a portion of an illustrative transmission system according to the invention. The portion of the illustrative transmission system may include six populated quantum dots 304, microwave generator 420, component 410 and component 418. In FIG. 5B, microwave transmitter 422 is generating microwave signal 502. Additionally, component 410 has a negative electric charge, and component 410 has a positive electric charge. The net effect of the magnetic field generated by microwave transmitter 422, and the electric field generated by components 410 and 418, is the alignment of the spin of the electron included in each quantum dot 304 along the direction S7.

In an exemplary communication system according to the invention, the alignment of the spin of the electrons included in quantum dots 304 along the direction of S7 may be used by a communication system according to the invention a way to transmit the binary bit ‘0’ to a receiver.

FIG. 5C shows a portion of an illustrative transmitting system according to the invention. The portion of the illustrative transmission system may include six populated quantum dots 304, microwave generator 420, component 410 and component 418. In FIG. 5C, microwave transmitter 424 is generating microwave signal 504. Additionally, component 410 has a positive charge and component 418 has a negative charge.

The net effect of the magnetic field generated by microwave transmitter 422, and the electronic field generated by components 410 and 418, is the alignment of the spins of the electrons in each quantum dot 304 along the direction S8.

In an exemplary communication system according to the invention, the alignment of an electron with the illustrated spin S8 may be used by a communication system according to the invention a way to transmit the binary bit ‘1’ to a receiver.

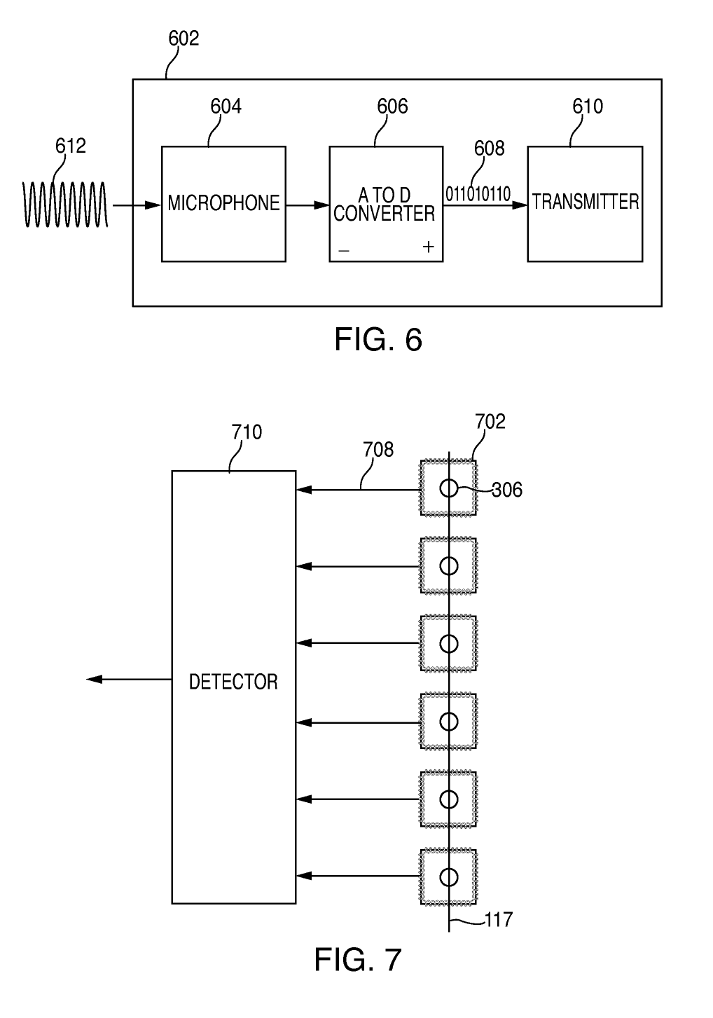

FIG. 6 shows illustrative apparatus 602 that incorporates a transmitter according to the invention. Illustrative apparatus 602 may be a portion of a computer, phone, cell phone, or any other apparatus that receives an input signal and subsequently transmits the signal to a receiver.

In FIG. 6, sound wave 612 is received by microphone 604. Microphone 604 transmits sound wave 612 to Analog to Digital Converter 606. Analog to Digital Converter 606 converts sound wave 612 into digital signal 608. Analog to Digital Converter 606 then transmits digital signal 608 to transmitter 610. Transmitter 610 then transmits each bit received from the digital signal by manipulating the spin of a group of entangled electrons into one of two predetermined directions.

For example, transmitter 610 may transmit a ‘0’ by applying a first electromagnetic field to the group of entangled electrons, aligning the spin of the electrons in a first direction. Transmitter 610 may transmit a ‘1’ by applying a second electromagnetic field to the group of electrons, aligning the spin of the electrons in a second direction.

FIG. 7 shows a portion of an illustrative receiving system according to the invention. In some embodiments, FIG. 7 may be a detailed view of quantum ensemble 113.

The receiving system illustrated in FIG. 7 may include detector 710 and channels 708. The receiving system may also include quantum dots 306, spin detectors 702, and electron transport channel 117.

Each of spin detectors 702 may include apparatus that enables detector 710 to detect the spin of an electron included in the quantum dot 306. For example, spin detector 702 may consist of a set of magnetic and/or electrical solid state components located on opposing sides of a quantum dot. Alternatively the solid state components may circumscribe the quantum dot. The solid state components may also, or alternatively, enclose the quantum dot on four sides, or completely surrounds the quantum dot. This configuration may enable spin detector 702 to indirectly read any change to the spin of the enclosed quantum entangled electrons.

Exemplary apparatus for indirectly reading a change to an electron's spin state includes ESR, SQUIDS, and any other suitable method. For example, in some embodiments that use SQUIDS to read a change in an electron's spin state, the apparatus may include superconducting wires that surround each quantum dot 306. In these embodiments, if the electron spin changes, the wire may detect a change in an electrical or electromagnetic field. This change in field may induce a current in the superconducting wire, which is then transmitted to detector 710.

Each of spin detectors 702 may feed an electrical signal into channel 708. The signal fed into channel 708 may correspond to the spin of an electron surrounded by spin detector 702. Detector 710 may receive the signals from channels 708. Detector 710 may use the signals to identify the spins of the electrons contained in the populated quantum dots 306.

Although FIG. 7 illustrates apparatus for using electrical and/or magnetic fields to detect the change in spin of entangled electrons, other apparatus such as lasers can be used to manipulate the electron spin, as detailed in “E” above.

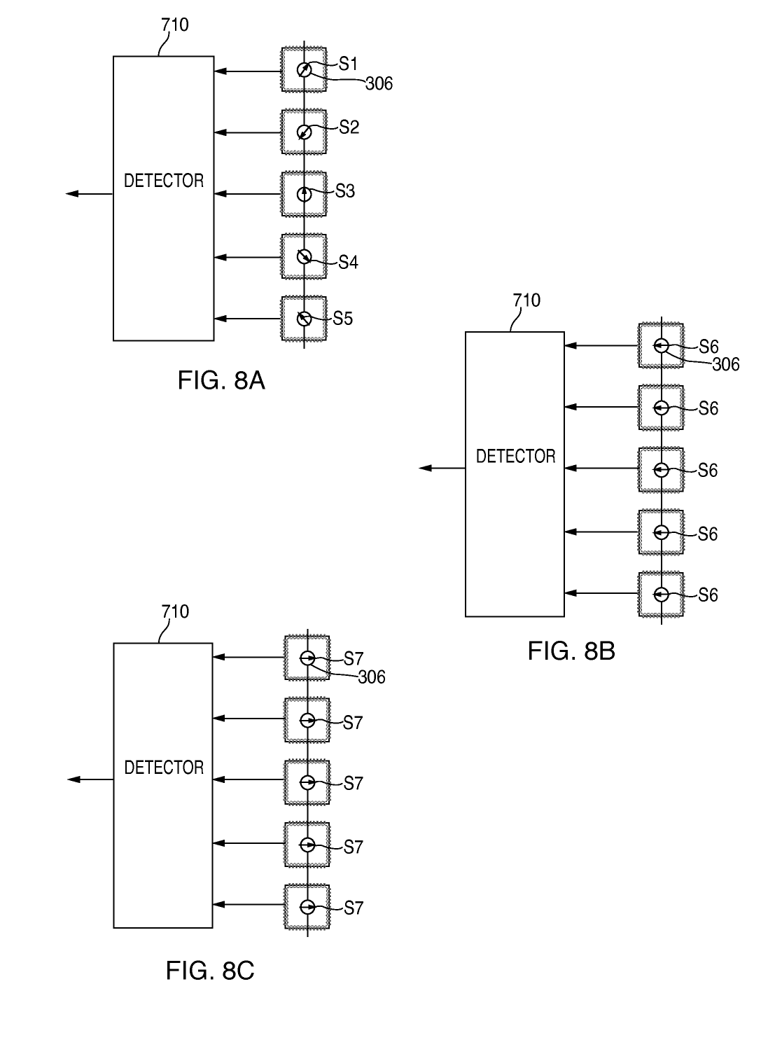

FIG. 8A shows detector 710 and the spins of the electrons included in quantum dots 306. In FIG. 8A, the electron spins of the quantum entangled electrons are S1, S2, S3, S4 and S5, each spin being different from the next. In an exemplary communication system according to the invention, the signal generated by spins S1, S2, S3, S4 and S5 may be equivalent to a ‘no data is being transferred’ signal, or a lack of signal.

FIG. 8B shows detector 710 and the spins of the quantum entangled electrons included in quantum dots 306. In FIG. 8B, each of the quantum entangled electrons have the spin S6. In an exemplary communication system according to the invention, the field generated by five spins S6 may result in the transmission of a signal to detector 710 that is read by detector 710 as an input of the binary value ‘0.’

The alignment of the spin of the electrons in FIG. 8B is a direct result of the alignment of the electrons in FIG. 5C. This is because each electron illustrated in FIG. 5C is in a quantum entangled state with one of the electrons illustrated in FIG. 8B. As a result, the manipulation of the spin of the electrons in FIG. 5C, using electronic and magnetic fields, results in the spins of the electrons in FIG. 8B taking on the spin correlated to the spin of the electrons in FIG. 5C.

FIG. 8C shows detector 710 and the spins of the quantum entangled electrons included in quantum dots 306. In FIG. 8C, each of the quantum entangled electrons have the spin S7. In an exemplary communication system according to the invention, the field generated by five spins S7 may result in the transmission of a signal to detector 710 that is read by detector 710 as an input of the binary value ‘1.’

The alignment of the spin of the electrons in FIG. 8C is a direct result of the alignment of the electrons in FIG. 5C. This is because each electron illustrated in FIG. 5C is in a quantum entangled state with one of the electrons illustrated in FIG. 8C. As a result, the manipulation of the spin of the electrons in FIG. 5C, using electronic and magnetic fields, results in a corresponding manipulation of the spins of the electrons in FIG. 8C.

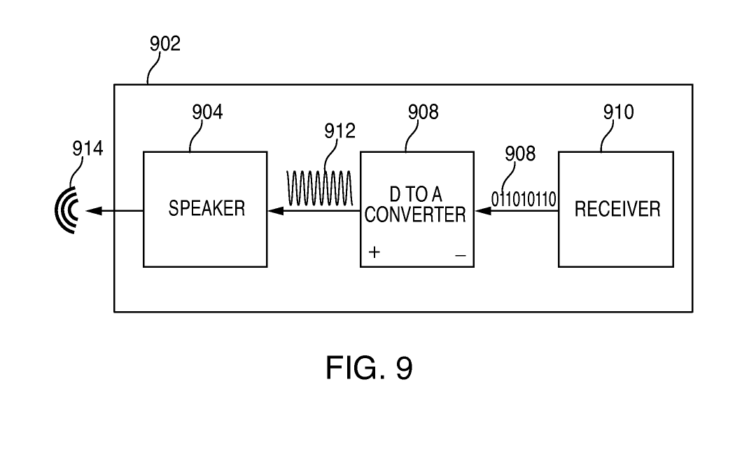

FIG. 9 shows illustrative apparatus 902 that may be used as a receiver in one or more electronic devices. Apparatus 902 may be incorporated into any suitable electronic device, such as a computer, phone, cell phone, or any other apparatus that receives and transmits a signal.

In FIG. 9, receiver 910 may be a receiver in accordance with the invention. Receiver 910 may receive signals that correlate to the spins of a group of quantum entangled electrons. Receiver 910 may process the received signals and transform them into binary output 908. Receiver 910 may transfer binary output 908 to a Digital to Analog Converter 908. Digital to Analog Converter 908 may generate analog signal 912 from binary output 908 and transmit analog signal 912 to speaker 904. Speaker 904 may use analog signal 912 to output sound 914.

Additional apparatus in accordance with the invention may include one or more of the apparatus illustrated in both FIG. 6 and FIG. 9. Any electronic device that requires transmitting may incorporate such apparatus.

In some embodiments, the systems and methods may include transmitting data based on the orientation of an electron's spin, as described above. In these embodiments, the transmitter may use optical methods, or electrical and/or magnetic fields to force the spin of the quantum entangled electrons in a certain direction. The receiver may receive data that corresponds to the orientation of the spins of the electrons. For example, the data received may include the arc surface orientation of the spins using first and second orthogonal angular values such as theta and phi. In these embodiments, a much larger volume of data transmission may be possible with each spin manipulation. For example, each value of theta and phi may range from −180 to 180 and may be evaluated to be a value in that range. The value may have any suitable size, such as fractions of a degree of arc, a degree of arc, two degrees of arc, 5, 10, 20, 30, 45, 60 or any other suitable size.

Additionally, quantum ensembles 111 and 113 may include any suitable number of populated quantum dots, in the order of tens, hundreds, thousands, or even tens of thousands of electrons. In these embodiments, a plurality of portions of each quantum ensemble may be used to send or receive data. For example, quantum ensemble 111 may include three hundred populated quantum dots. A block of thirty populated quantum dots, for example, may be used to transmit a single signal. As a result, each block of quantum dots may be manipulated/detected separately. This may enable multiple pieces of data to be transmitted simultaneously, or substantially simultaneously. Alternately, each block of quantum dots may be manipulated/detected upon the lapse of a predetermined time period.

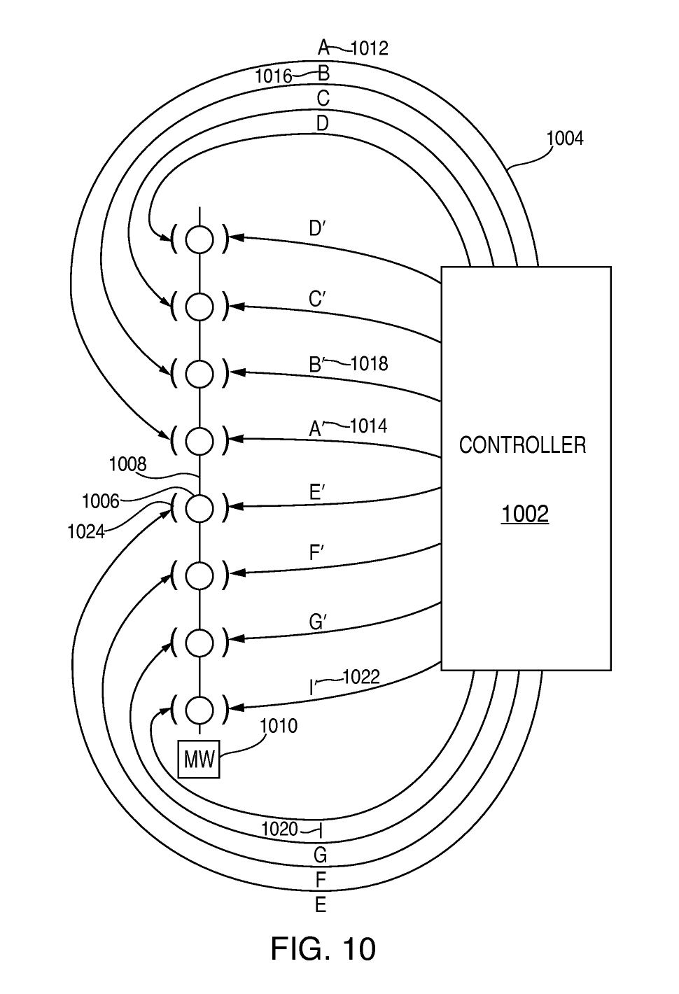

FIG. 10 shows illustrative apparatus that may be included in a transmitter. The apparatus may include controller 1002. Controller 1002 may control the voltage of conductors 1004. Each conductor may have a potential, current, charge or voltage represented by A through E, or A′ through E′. Each conductor may be in electronic communication with a different generator 1024.

Each quantum dot 1006 may be surrounded by two generators 1024. Each quantum dot 1006 may be connected to transport channel 1008.

Microwave generator 1010 may be located at the “bottom’ of row of quantum dots 1006.

In some embodiments, the potential, current, charge or voltage of a first generator surrounding a quantum dot may be the opposite potential, current, charge or voltage of a second generator surrounding the quantum dot. For example, charge 1012 may be opposite of charge 1014, charge 1016 may be the opposite of charge 1018 and charge 1022 may be the opposite of charge 1020. An example of a set of opposite charges are a positive charge and a negative charge.

Each quantum dot in FIG. 10 may be in close proximity to two generators 1024. It should be noted that generators 1024 may generate electric fields, magnetic fields, and/or electromagnetic fields. The proximity may assist in calibration. The proximity may provide control in addition to providing a high level control in spin manipulation enabling specific spin states to be attained. This may enable each quantum dot to transmit a single piece of information without having to use a large group of quantum dots for the transmission of a single piece of information.

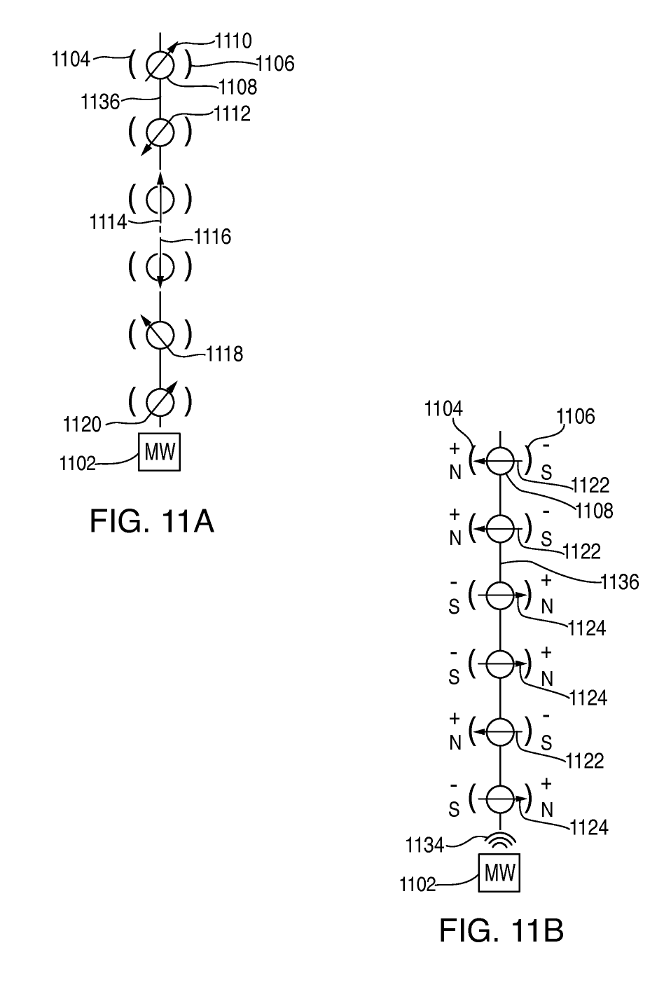

FIG. 11A shows illustrative apparatus that may be included in a transmitter. The illustrative apparatus may include generators 1104 and 1106 located on either side of each quantum dot 1108. Each quantum dot may be connected to transport channel 1136. The spins of the electrons located in each quantum dot 1108 may be random and are represented by spin 1110, spin 112, spin 1114, spin 1116, spin 1118 and spin 1120.

Microwave generator 1102 is located at the bottom of channel 1136. In the state illustrated in FIG. 11A, the microwave generator is not generating any waves and generators 1104 and 1106 are not charged. Thus, the electron spins are random and have no uniform characteristic.

FIG. 11B shows illustrative apparatus that may be included in a transmitter. The apparatus may include generators 1104 and 1106 surrounding each quantum dot 1108. The quantum dots may be connected by transport channel 1108.

In the state illustrated in FIG. 11B, microwave generator 1102 is generating microwaves 1134, and generators 1104 and generators 1106 have been charged with either a positive or a negative charge. In a pair of generators surrounding quantum dot 1108, one generator has a charge opposite from the charge of the other generator.

As a result of the microwaves and the charged generators, the spins of the electrons in quantum dots 1108 are illustratively either spin 1122 or spin 1124.

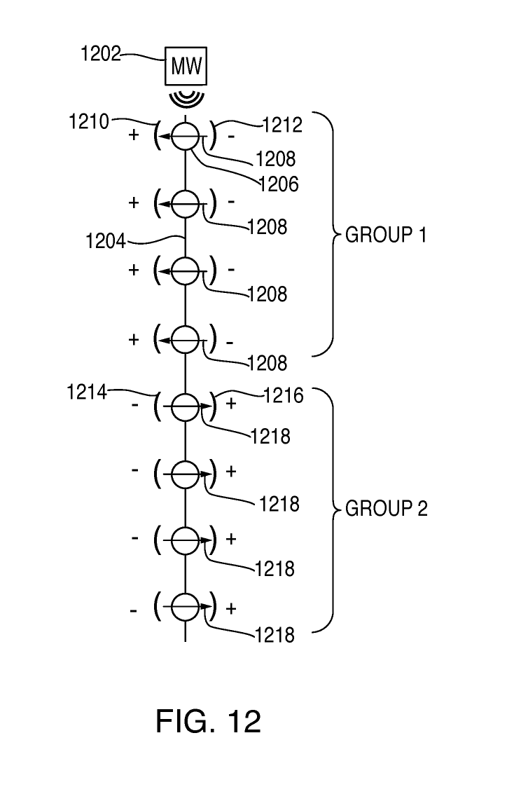

FIG. 12 shows illustrative apparatus that may be in included in a transmitter. The apparatus may include generators 1210 and 1212 surrounding each quantum dot 1206. The quantum dots 1206 may be connected to transport channel 1204.

In the state illustrated in FIG. 12, microwave generator 1202 is emitting microwaves and generators 1210 and 1212 are polarized. A first piece of information (the alignment of the electron spins along the direction of spin 1208) is transmitted by Group 1. A second piece of information (the alignment of the electron spins along the direction of spin 1218) is transmitted by Group 2.

The Groups may be used to transmit data simultaneously.

In some embodiments, the Groups may be used to transmit symbols. The symbols may include, for example, ASCII alphanumeric characters. For example, eight groups may be included in a transmitter. A digital data stream in the form of a datagram may be received by the controller or by a device in electronic communication with the controller. The digital data stream may then undergo BASE64 encoding. The encoding may encode the binary data into an ASCII alphanumeric stream. The alphanumeric stream may be transmitted by the transmitter by transmitting one ASCII alphanumeric character at a time. Because an alphanumeric character includes eight binary digits, each of the eight groups may be responsible for transmitting one of the binary digits of the alphanumeric character simultaneously to a receiver.

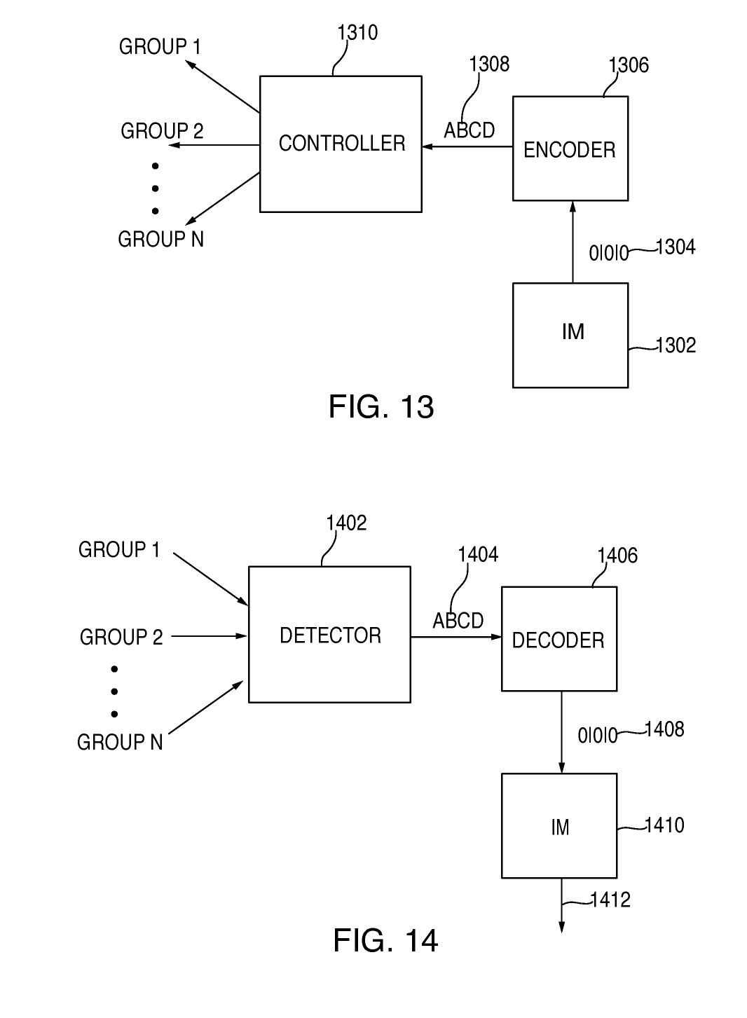

FIG. 13 shows illustrative apparatus that may be used to transmit information from a QCN or from any other suitable device. IM 1302 transmits binary data 1304 to encoder 1306. Encoder encodes binary data 1304 into ASCII alphanumeric stream 1308 that is transmitted to controller 1310. Controller 1310 uses one group from each of n Groups to transmit a bit of data that may be used to identify an alphanumeric character that is included in the alphanumeric stream. In embodiments in which an alphanumeric character is identified using 8 bits of data, controller 1310 may manipulate 8 groups simultaneously to transmit an alphanumeric character, with each group being designated to transmit one of the bits of data.

FIG. 14 shows illustrative apparatus that may be used to receive data in a QCN or any other suitable device.

In FIG. 14, detector 1402 may detect changes of spins of electrons included in the n groups. The measured data may be fed into detector 1402. Detector 1402 may decode the specific patterns sent by controller 1310 into an alphanumeric signal 1404 which is then transmitted to decoder 1406. Decoder 1406 may decode alphanumeric signal 1404 into a binary data stream 1408, such as a datagram, which is transmitted to IM 1410. IM 1410 transmits the data along 1412 to a different destination, such as a different network destination included in the QCN.

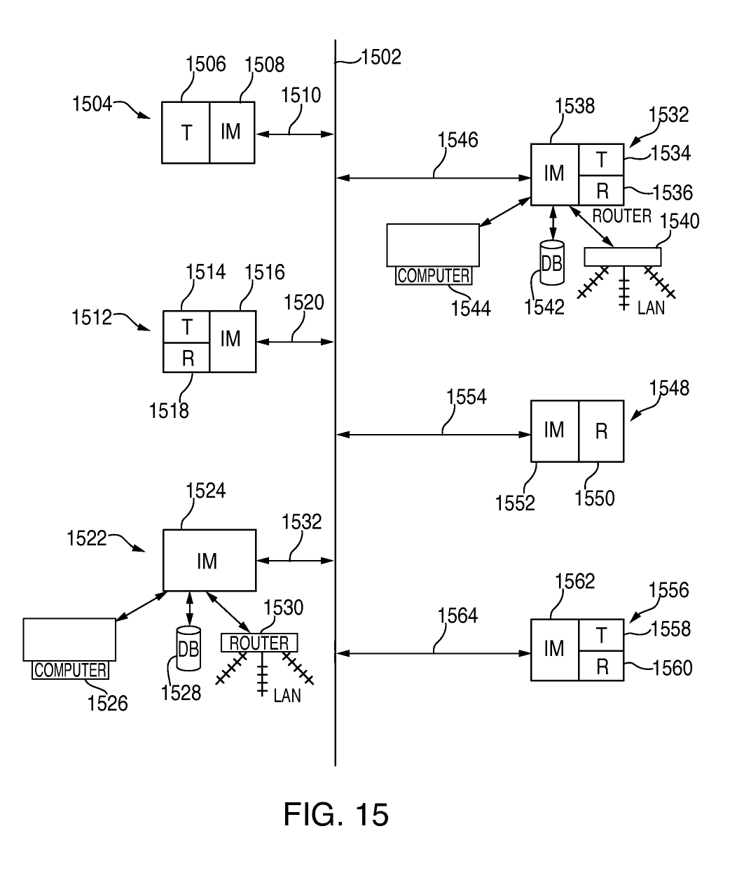

FIG. 15 shows an illustrative portion of a QCN that may include backbone 1502 and a plurality of network interfaces.

Each network interface may be used to receive and/or transmit information between the QCN and an electronic device using quantum entangled electrons as described herein. Each network interface may include a network interconnector. The network interconnector may enable a device in communication with the QCN to receive and/or transmit data from any other device in communication with the QCN as described in Section J above.

The QCN may include network interface 1504. Network interconnector 1504 may include transmitter 1506, IM 1508 and network interconnector 1504.

Network interface 1504 may represent a device that is in one-way communication with the QCN. The device may receive data from the QCN, but may be configured to be unable to transmit data to the QCN.

The QCN may include network interface 1512. Network interface 1512 may include transmitter 1514, receiver 1518, IM 1516 and network interconnector 1520.

Network interface 1512 may represent a device in two-way communication with the QCN. The device may receive and transmit data to the QCN.

The QCN may also include network interface 1522. Network interface 1522 may include IM 1524 and network interconnector 1532. In network interface 1522, IM 1524 may be connected to computer 1526, database 1528 and router 1530 using one or more conventional communication medium such as wires, cables or electrical signals.

Network interface 1522 may represent a connection between the QEM and a plurality of devices using conventional transmission mediums. IM 1524 may receive data transmitted by the devices and then transmit the data over backbone 1502 to other network interfaces included in the QEM. The QEM may then transmit the data to one or more devices using one or more transmitters. IM 1524 may receive data from the QEM and transmit the data to one or more devices using conventional transmission mediums.

Network interface 1522 enables a device that transmits and receives data using transmitters and receivers according to the invention to be in two-way communication with devices that do not support quantum-based communications with the QEM.

The QCN may also include network interface 1532. Network interface 1532 may include transmitter 1534, receiver 1536, IM 1538 and network interconnector 1546. IM 1538 may be connected to computer 1544, database 1542 and router 1540 using one or more conventional communication media such as wires, cables or electrical signals.

The QCN may include network interface 1548. Network interface 1548 may include router 1550, IM 1552 and network interconnector 1554.

Network interface 1548 may represent a one-way connection between a device and the QEM. The one-way connection may enable the device to transmit information to the QEM, but may be configured to be unable to receive information from the QEM.

The QCN may include network interface 1556. Network interface 1556 may include transmitter 1558, receiver 1560, IM 1562 and network interconnector 1564.

Some devices may be in communication with the QCN using two or more channels. For example, a device may have two or more transmitters or receivers in communication with the QCN. In these embodiments, a network interface included in the QCN that supports the receipt and transmission of data to and from the device may have the corresponding transmitter(s) and/or receiver(s) included in the network interface. These multiple channels may be used by the QCN for simultaneous streaming of two or more sets of data to and from the devices.

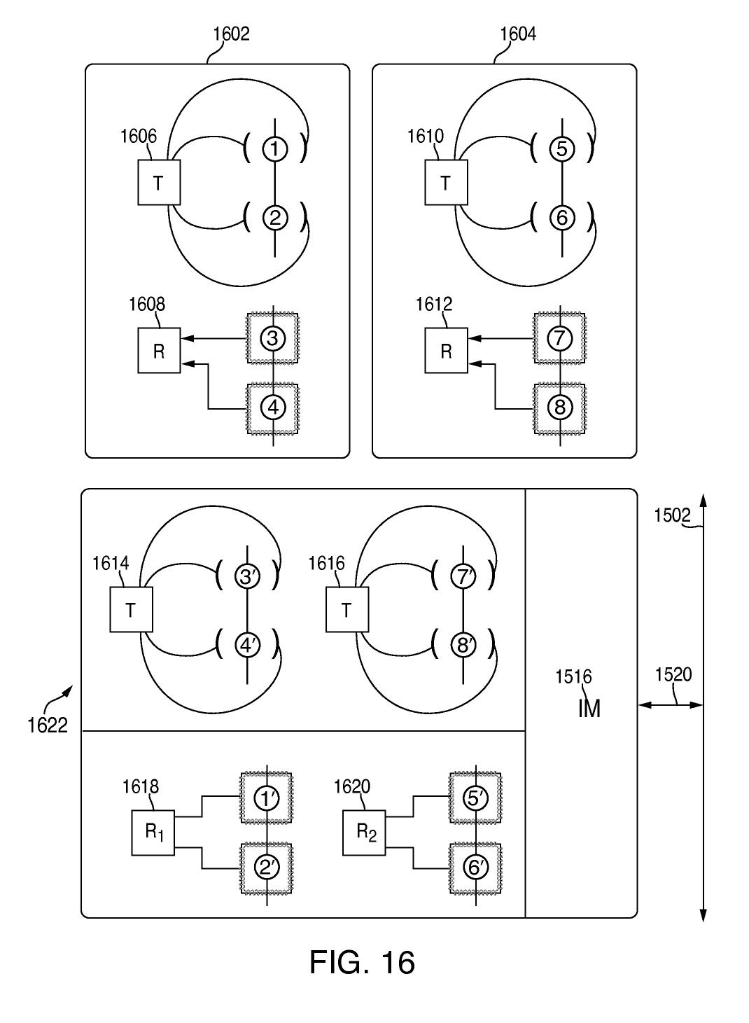

FIG. 16 shows illustrative apparatus that may include electronic device 1602 and electronic device 1604. Electronic devices 1602 and 1604 may be any suitable electronic device such as a telephone, computer, radio, etc.

Electronic device 1602 may include transmitter 1606. Transmitter 1606 may include quantum entangled electrons 1 and 2. Electronic device 1602 may also include receiver 1608. Receiver 1608 may include quantum entangled electrons 3 and 4.

The spin of an electron i included in FIG. 16 may be in a quantum entangled state with the spin of an electron i′ included in FIG. 16. For example, the spin of electron 3 is in a quantum entangled state with the spin of electron 3′.

Electronic device 1604 may include transmitter 1610. Transmitter 1606 may include quantum entangled electrons 5 and 6. Electronic device 1604 may also include receiver 1612. Receiver 1608 may include quantum entangled electrons 7 and 8.

FIG. 16 includes an illustrative portion of a QCN that may include network interconnector 1520, network backbone 1502, and network interface 1622.

Network interface 1622 may receive data from device 1602 and 1604. Network interface 1622 may receive data transmitted by transmitter 1606 via receiver 1618. Network interface may receive data transmitted by transmitter 1610 via receiver 1620.

Network interface 1622 may transmit data to device 1602 and device 1604. Network interface may transmit data from transmitter 1614 to receiver 1608 included in device 1602. Network interface 1622 may also transmit data from transmitter 1616 to receiver 1612 located included in device 1604.

Network interface 1622 includes the corresponding pair of electrons incorporated in transmitter 1606, receiver 1608, transmitter 1610 and receiver 1612. Therefore network interface 1622 may be able to support two way communications between the network and devices 1602 and 1604.

In these embodiments, communication between devices 1602 and 1604 is handled by IM 1516 and may not need to be transmitted through network backbone 1502. However, any information to be transferred between one of devices 1602 or 1604 and a different device may be transferred by the IM 1516 to network interconnector 1520 and over network backbone 1502 to a destination address specified in a portion of the data to be transmitted.

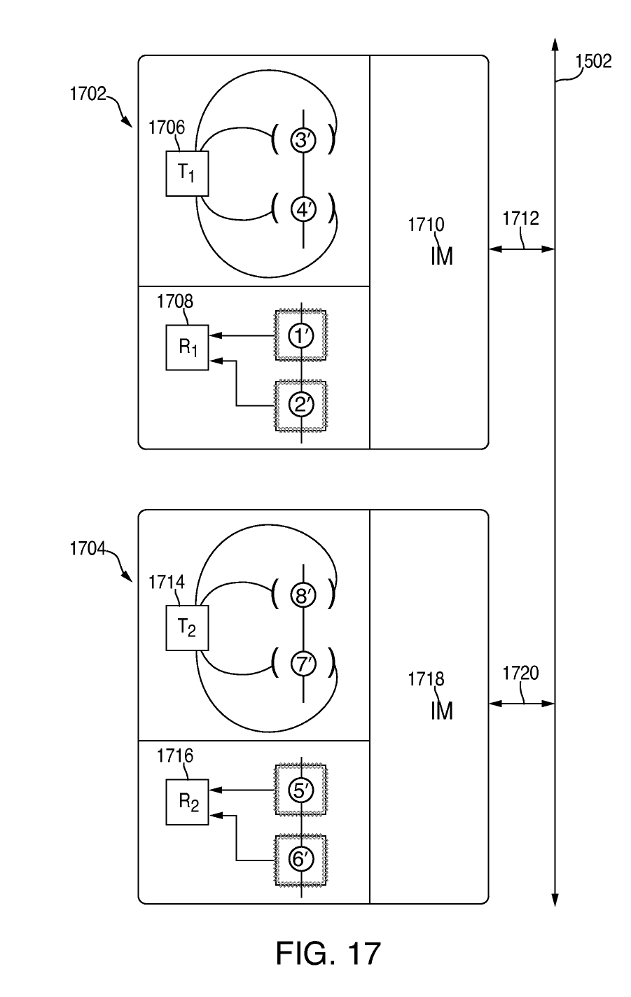

FIG. 17 includes illustrative apparatus that may represent be a portion of a QCN that may include network interface 1702 and network interface 1704. Network interface 1702 may include transmitter 1706, receiver 1708 and IM 1710. Network interface 1702 may support two way communication between the network and device 1602. For data to be transferred between network interface 1702 and a different device, the data must be transferred by IM 1710 to network interconnector 1712 and over network backbone 1502 to a destination address specified in a portion of the data to be transmitted.

Network interface 1704 may include transmitter 1704, receiver 1716 and IM 1718. Network interface 1704 may support two way communication between the network and device 1604. For data to be transferred between network interface 1704 and a different device, the data must be transferred by IM 1718 to network interconnector 1718 and over network backbone 1502 to a destination address specified in a portion of the data to be transmitted.

The spin of an electron i included in FIG. 17 may be in a quantum entangled state with the spin of an electron i′ included in FIG. 16. The spin of an electron i′ included in FIG. 17 may be in a quantum entangled state with the spin of an electron i included in FIG. 16. For example, the spin of electron 3 included in FIG. 16 is in a quantum entangled state with the spin of electron 3′ included in FIG. 17.

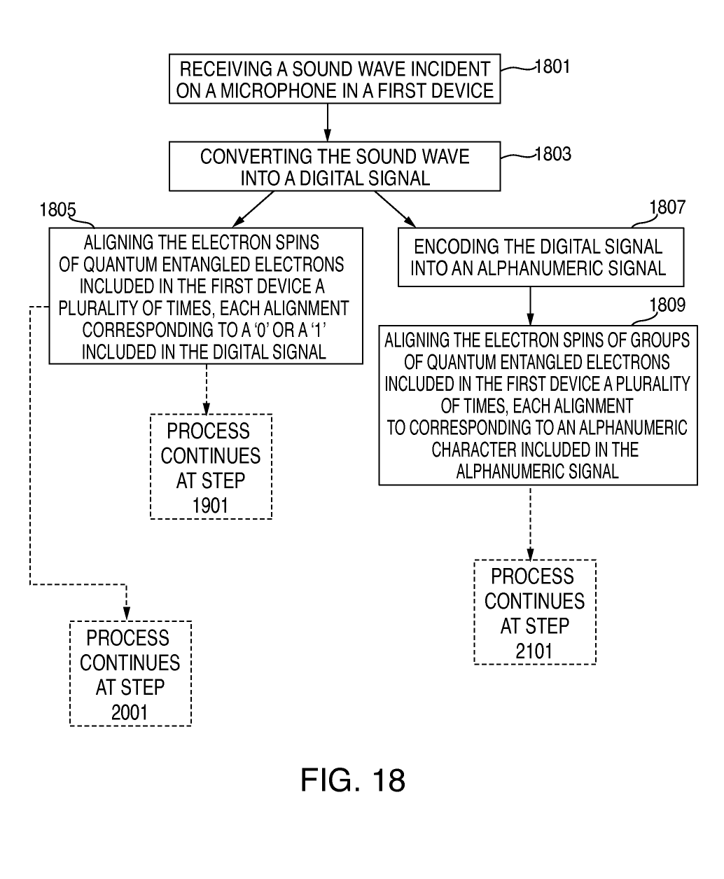

FIG. 18 shows an exemplary process that may include one or more of steps 1801-1809.

At step 1801, the process may include receiving a sound wave incident on a microphone in a first device. The process may also include converting the sound wave into a digital signal at step 1803. The process may continue at either step 1805 or at step 1807.

At step 1805, the process may include aligning the electron spins of quantum entangled electrons included in the first device a plurality of times. Each alignment may correspond to a “0” or a “1” included in the digital signal. The process may optionally continue at step 1901 or at step 2001 described below.

At step 1807, the process may include encoding the digital signal into an alphanumeric code. At step 1809, the process may include aligning the electron spins of groups of quantum entangled electrons included in the first device a plurality of times. Each alignment may correspond to an alphanumeric character included in the alphanumeric signal. The process may then optionally continue at step 2101 described below.

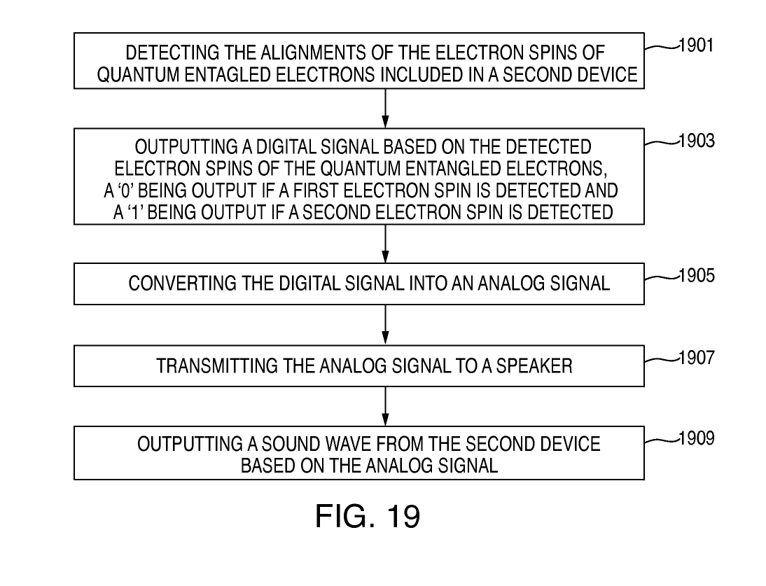

FIG. 19 shows an exemplary process that may include one or more of steps 1901-1909.

At step 1901, the process may include detecting the alignments of the electron spins of quantum entangled electrons included in a second device. A physical characteristic of each of the quantum entangled electrons included in the second device may be in a quantum entangled state with a physical characteristic of a quantum entangled electron included in the first device identified in connection with FIG. 18 above.

At step 1903, the process may include outputting a digital signal based on the detected electron spins of the quantum entangled electrons. A ‘0’ may be output if a first electron spin is detected and a ‘1’ may be output if a second electron spin is detected.

The process may continue at step 1905. At step 1905, the process may include converting the digital signal into an analog signal. The analog signal may be transmitted to a speaker at step 1907. At step 1909, the process may include outputting a sound wave from the second device based on the analog signal.

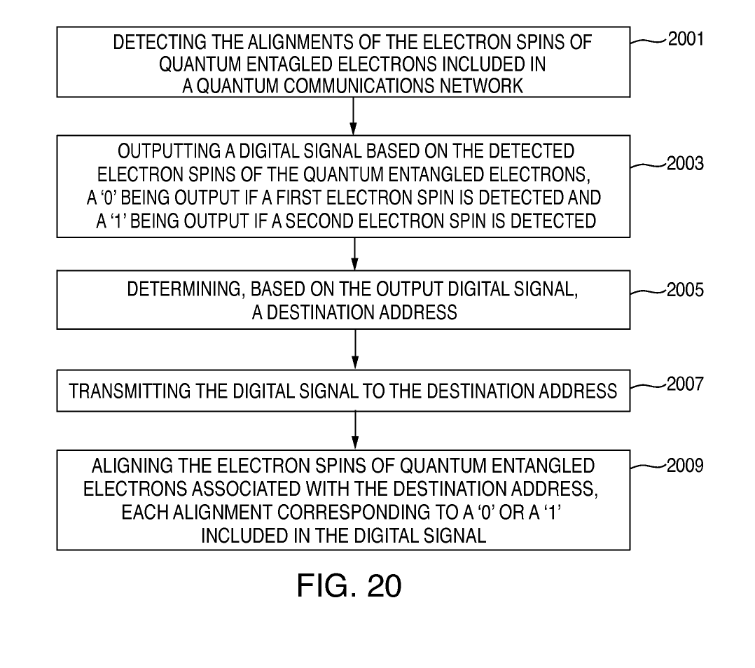

FIG. 20 shows an exemplary process that may include one or more of steps 2001-2009.

At step 2001, the process may include detecting the alignments of the electron spins of quantum entangled electrons included in a quantum communications network. Each of the electron spins may be in a quantum entangled state with the electron spins of electrons included in the first device identified in connection with FIG. 18 above.

At step 2003, the process may include outputting a digital signal based on the detected electron spins of the quantum entangled electrons. A “0” may be output if a first electron spin is detected and a “1” may be output if a second electron spin is detected.

The process may continue at step 2005. At step 200, the process may include determining, based on the output digital signal, a destination address. A digital signal may be transmitted to the destination address at step 2007. At step 2009 the process may include aligning the electron spins of quantum entangled electrons associated with the destination address. Each alignment may correspond to a “0” or a “1” included in the digital signal.

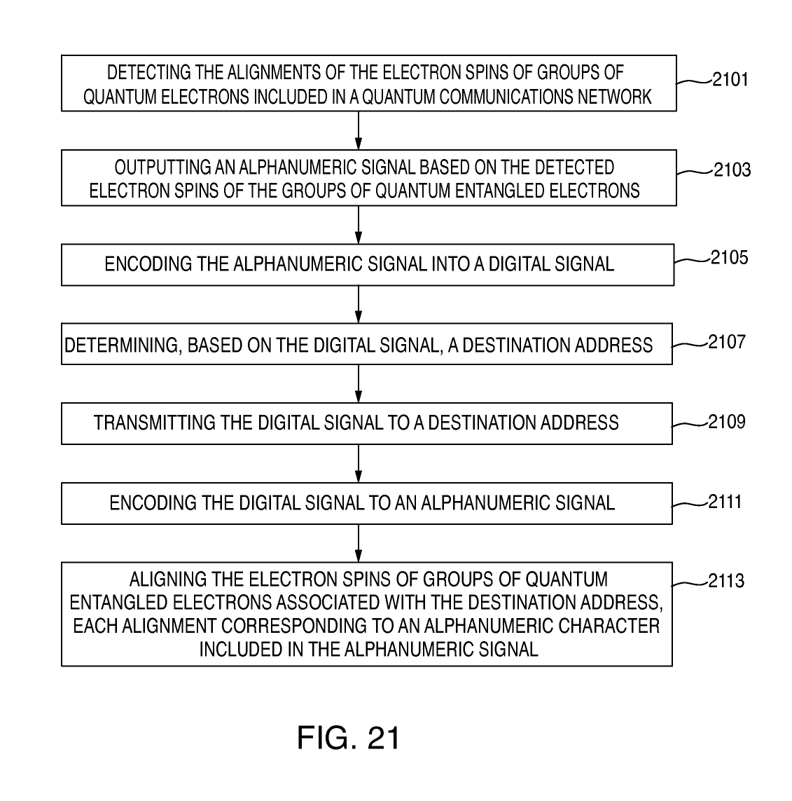

FIG. 21 shows an exemplary process that may include one or more of steps 2101-2113.

At step 2101, the process may detect the alignments of the electron spins of groups of quantum electrons included in a quantum communications network. Each of the electron spins in a group of electrons in the QCN may be in a quantum entangled state with an electron spin of an electron in a group of quantum entangled electrons in the first device described in FIG. 18 above.

At step 2103, the process may output an alphanumeric signal based on the detected electron spins of the groups of quantum entangled electrons. At step 2105, the process may encode the alphanumeric signal into a digital signal. At step 2107, the process may determine, based on the digital signal, a destination address. At step 2109, the process may transmit the data signal to the destination address. At step 2111, the process may encode the digital signal to an alphanumeric signal.

The process illustrated in FIG. 21 may end at step 2113. At step 2113, the process may align the electron spins of groups of quantum entangled electrons associated with the destination address. Each alignment may correspond to an alphanumeric character included in the alphanumeric signal.

Thus, methods and apparatus for transmitting and receiving data using quantum entangled electrons have been provided. Persons skilled in the art will appreciate that the present invention can be practiced in embodiments other than the described embodiments, which are presented for purposes of illustration rather than of limitation, and that the present invention is limited only by the claims that follow.

What is claimed is:

1. Apparatus for arranging a group of electrons, the apparatus comprising:
a first quantum ensemble including a first row of quantum dots and a second quantum ensemble including a second row of quantum dots;
a beam splitter configured to inject a first particle into a first quantum dot and a second particle into a second quantum dot, wherein a physical property of the first particle is in a quantum-entangled state with a physical property of the second particle;
a first wave source configured to move the first particle from the first quantum dot into a quantum dot in the first row of quantum dots, and to move the second particle from the second quantum dot into a quantum dot in the second row of quantum dots;
a second wave source configured to move the first particle along the first row of quantum dots; and
a third wave source configured to move the second particle along the second row of quantum dots.

2. The apparatus of claim 1 wherein the first quantum dot and the second quantum dot are part of a carbon nanotube.

3. The apparatus of claim 1 wherein the first particle is a first electron, the second particle is a second electron, and the physical property is an electron spin.

4. The apparatus of claim 1 wherein the first wave source comprises a microwave signal.

5. The apparatus of claim 1 further comprising:
a first laser configured to apply a pulse beam to the first particle to manipulate the physical property of the first particle; and
a second laser configured to apply a probe beam to the second particle to measure the physical property of the second particle.

6. The apparatus of claim 5 wherein the first laser applies the pulse beam using optical pulses.

7. The apparatus of claim 3 further comprising:
first apparatus configured to apply a field to the first electron, wherein the application of the field alters the spin of the first electron; and
second apparatus configured to detect a change in the spin of the second electron.

8. The apparatus of claim 7 wherein the first apparatus comprises:
a first electromagnet located on a first side of the first electron; and
a second electromagnet located on a second side of the first electron opposite the first side,
wherein:
the first apparatus is configured to apply a field to the first electron by applying a voltage to the first electromagnet and the second electromagnet.

9. The apparatus of claim 7 wherein the second apparatus comprises a superconducting quantum interference device “SQUID” that includes superconducting wires configured to circumscribe the second electron.

10. The apparatus of claim 9 wherein:
the SQUID is configured to detect the change in the spin of the second electron by detecting a change in an electric field surrounding the second electron; and
the change in the electric field surrounding the second electron is effected by the altering of the spin of the first electron.

11. A method for making ensembles of quantum dots, the method comprising:
fabricating a substrate including a beam splitter, a first transport channel extending away from the beam splitter and attached to a beginning of a first ensemble of quantum dots, and a second transport channel extending away from the beam splitter and attached to a beginning of a second ensemble of quantum dots.

12. The method of claim 11 further comprising:
generating quantum entangled electrons using the beam splitter; and
populating the first ensemble of quantum dots and the second ensemble of quantum dots with the quantum entangled electrons.

13. The method of claim 12 further comprising cutting the wafer, wherein the cutting separates the first ensemble of quantum dots from the second ensemble of quantum dots.

14. The method of claim 12 wherein the beam splitter includes a superconductor and the generating includes ejecting a Cooper pair from the superconductor.

15. The method of claim 13 further comprising incorporating the first ensemble into a first electronic device and incorporating the second ensemble into a second electronic device.

16. The method of claim 15 further comprising:
using the first ensemble to transmit information from the first electronic device to the second electronic device; and
using the second ensemble to receive the transmitted information.

17. The method of claim 13 wherein:
the first ensemble is configured to transmit information by aligning at least a portion the spins of the quantum entangled electrons included in the first ensemble along a first direction; and
the second ensemble is configured to receive information by detecting the corresponding change in spins of at least a portion of the quantum entangled electrons included in the second ensemble.

18. The method of claim 11 wherein the fabricating further includes positioning the end of the first ensemble of quantum dots at a distance at least 2.5 cm away from the end of the second ensemble of quantum dots.

19. A transmitter configured to transmit data by manipulating a spin of an electron.

20. The transmitter of claim 19 wherein:
the electron is a first electron; and
the electron spin of the first electron is in a quantum entangled state with an electron spin of a second electron.

21. The transmitter of claim 19 wherein the transmitter is disposed in a first device and is configured to transmit information to a receiver disposed in a second device.

22. The transmitter of claim 21 wherein the first device is different from the second device.

23. The transmitter of claim 22 wherein the first device is a mobile phone and the second device is a communication network.

24. The transmitter of claim 19 wherein the manipulating comprises generating an electromagnetic signal proximate to the electron.

25. The transmitter of claim 19 wherein the quantum entangled electron is retained by a quantum dot.

26. The transmitter of claim 25 wherein:
the quantum entangled electron is part of a first quantum ensemble that includes a plurality of quantum entangled electrons; and
each quantum entangled electron in the first quantum ensemble is in an entangled state with an electron in a second quantum ensemble.

27. A method for transmitting information, the method comprising manipulating a spin of a first electron, wherein the spin of the first electron is in a quantum entangled state with a spin of a second electron.

28. A receiver configured to receive data by detecting a field generated by a change in spin of an electron.

29. The receiver of claim 28 wherein:
the electron is first electron; and
the electron spin of the first electron is in a quantum entangled state with an electron spin of a second electron.

30. The receiver of claim 28 wherein the field is detected by a superconducting conductor circumscribing the electron.

31. The receiver of claim 29 wherein the change in spin of the first electron is induced by a change in spin of the second electron.

32. The receiver of claim 28 wherein the field corresponds to one of the binary values 1 and 0.

33. The receiver of claim 32 further comprising a processor that is configured to output the one of the binary values 1 and 0.

34. A receiver configured to pulse an ensemble of quantum entangled electrons to receive data.

35. The receiver of claim 34 wherein:
the ensemble of quantum entangled electrons is configured to be pulsed using a laser; and
the laser is configured to provide an ellipticity for measuring a precession of spins of the quantum entangled electrons.

36. A method of receiving information, the method comprising detecting a field generated by a change in an electron spin of an electron.

37. Apparatus comprising:
a receiver configured to receive instructions from a user to transmit a piece of information to a destination; and
a transmitter configured to transmit the information to a controller that is configured to transmit the information to the destination by manipulating the spin of an electron.

38. The apparatus of claim 37 wherein:
the electron is a first electron; and
the spin of the first electron is in a quantum entangled state with a spin of a second electron located in a communication network.

39. The apparatus of claim 38 wherein the first electron is in a first country and second electron is in a second country.

40. The apparatus of claim 38 wherein the piece of information includes a network address.

41. The apparatus of claim 40 wherein the network address identifies a location in the communication network.

42. The apparatus of claim 41 wherein the network address is an IP address.

43. Apparatus comprising:
a first electron including a first spin;
a second electron including a second spin; and
a generator that is configured to manipulate the first spin of the first electron to transmit a first packet of information to a first device and to manipulate a second spin of a second electron to transmit a second packet of information to a second device.

44. The apparatus of claim 43 wherein the first electron and the second electron are the same electron.

45. The apparatus of claim 43 wherein the first electron is different from the second electron.

46. The apparatus of claim 43 wherein the first packet includes first routing information and the second packet includes second routing information.

47. A method comprising manipulating an electron spin of an electron located in a first device to transmit information to a second device and to a third device.

48. A method for receiving information from a first device and transmitting the information to a second device comprising:
detecting a change in a physical property of a first quantum entangled particle, wherein the physical property of the first quantum entangled particle is in a quantum entangled state with a physical property of a second quantum entangled particle located in the first device;
outputting data based on the detected change;
transmitting the data through a network to a destination identified in the data stream;
manipulating a physical property of a third quantum entangled particle, wherein the physical property of the third quantum entangled particle is in a quantum entangled state with a physical property of a fourth quantum entangled particle located in the second device.

49. The method of claim 48 wherein the first quantum entangled particle and the third quantum entangled particle are located in a communication network.

50. The method of claim 48 wherein the detecting comprises sensing a change in an electromagnetic field surrounding the first quantum entangled particle.

51. The method of claim 48 wherein the manipulating comprises generating an electric, magnetic or electromagnetic field proximal to the third quantum entangled particle.

52. The method of claim 48 wherein the particles are electrons and the physical property is an electron spin.

53. The method of claim 48 wherein the first quantum entangled particle is part of a first group of quantum entangled particles, the second quantum entangled particle is part of a second group of quantum entangled particles, the third entangled particle is part of a third group of entangled particles, and the fourth entangled particle is part of a fourth group of entangled particles.

54. A method of manufacturing a communication network, the method comprising:
providing a receiver configured to receive information by detecting a change in a spin of a first electron;
providing a transmitter configured to transmit information by manipulating a spin of a second electron;
providing a network backbone;
configuring the receiver to be in electronic communication with a first interconnection module;
configuring the transmitter to be in electronic communication with a second interconnection module; and
configuring the first interconnection module and the second interconnection module to be in electronic communication with each other over the network backbone.
